(19) United States
(12) Patent Application Publication
(10) Pub. No.: US 2007/0169814 A1
(43) Pub. Date: Jul. 26, 2007

(54) Organic electronic devices incorporating semiconducting polymer brushes

(76) Inventors: Wilhelm T.S. Huck, Comberton (GB); Gregory L. Whiting, Cambirdge (GB); Richard Henry Friend, Cambridge (GB); Henry Snaith, Ely (GB)

Correspondence Address: GOODWIN PROCTER LLP;PATENT ADMINISTRATOR, EXCHANGE PLACE, BOSTON, MA, 02109-2881, US

(21) Appl. No.: 10/552,653

(22) PCT Filed: Apr. 21, 2004
(86) PCT No.: PCT/GB04/01696

§ 371 Date: Sep. 19, 2006

(30) Foreign Application Priority Data
Apr. 24, 2003 (GB) 0309355.6

(51) Int. Cl. H01L 31/00

(52) U.S. Cl. 136/263

(57) ABSTRACT

An organic electronic device comprises at least two electrodes and a semiconducting layer comprising a mixture of at least one hole-transporting semiconducting material and at least one electron-transporting semiconducting material, wherein at least one of said semiconducting materials is in the form of semiconducting polymer brushes which are attached to the surface of at least one of said electrodes and are in contact with at least one of said other semiconducting materials. Also provided is an organic electronic device comprising at least two electrodes and a semiconducting layer comprising at least one hole-transporting or electron-transporting semiconducting material, wherein said at least one semiconducting material is in the form of semiconducting polymer brushes which are attached to the surface of at least one of said electrodes. Processes for the manufacture of said devices are also provided.

### FIELD OF THE INVENTION

The present invention relates to organic electronic devices such as photovoltaic devices and organic electroluminescent devices, said devices comprising electrodes and a semiconducting layer comprising a mixture of at least one hole-transporting semiconducting material and at least one electron-transporting semiconducting material, wherein at least one of said semiconducting materials is in the form of semiconducting polymer brushes which are attached to the surface of at least one of said electrodes and are in contact with at least one of said other semiconducting materials. It also relates to organic electronic devices such as field effect transistors, said devices comprising electrodes and a semiconducting layer comprising at least one hole-transporting or electron-transporting semiconducting material, wherein said at least one semiconducting material is in the form of semiconducting polymer brushes which are attached to the surface of at least one of said electrodes. It also relates to methods for the manufacture of such devices.

### BACKGROUND TO THE INVENTION

In recent years organic semiconductor materials, including both semiconducting polymers and semiconducting small organic molecules have been used in the construction of various electronic devices including electroluminescent devices, photovoltaic devices, field effect transistors and liquid crystal devices. These materials have significant advantages, including the simplicity and low-cost of the manufacture of devices using said materials, flexibility of use and excellent performance characteristics. Research into novel materials, processing techniques and device geometries has resulted in significant improvements in stability, lifetime, and performance in all such devices.

Photovoltaic devices constructed from an anode and a cathode between which are sandwiched a blended binary system consisting of hole and electron-transporting organic and non-organic semiconductor materials are one example of such devices. These have shown high external quantum efficiencies (number of electrons collected at the cathode to incident photons upon devices). Photogeneration of charges within semiconductor material blends occurs by exciton dissociation at material heterojunctions, with charge transfer of the electron to one component of the blend and the hole to the other. Ideally, photovoltaic devices should have adequate thickness of the light-absorbing material within which photo-generation of charges takes place so that the amount of incident light used is maximised. In order to achieve high external quantum efficiency, the active material layer should consist of at least two components with distributed heterojunctions throughout the film, to aid charge separation, and direct transportation paths to each electrode within each component of the blend to maximise charge extraction.

It has been demonstrated that the performance of a photovoltaic device formed as a mixture of two semiconducting polymers can be greatly enhanced by controlling the blend morphology [see Snaith et al, Nano Letters 2002, 2(12), 1353-1357; Halls et al, Advanced Materials 2000, 12(7), 498-502; and Arias et al, Macromolecules 2001, 34, 6005-6013]. This is achieved by altering the device preparation parameters (solution and substrate temperatures, spin-speeds, solvent saturated atmosphere and by using different solvents). However, a significant loss mechanism in these devices is due to charge trapping, caused by a lack of direct transportation paths to each electrode within each component of the blend. There is a clear need for a new architecture for organic photovoltaic devices that maximises the distributed heterojunctions throughout the polymer blend, to aid charge separation, and provides direct transportation paths to each electrode within each component of the blend to maximise charge extraction.

In recent years, there has been considerable interest in light emitting organic materials such as conjugated polymers. Light emitting polymers possess a delocalised pi-electron system along the polymer backbone. The delocalised pi-electron system confers semiconducting properties to the polymer and gives it the ability to support positive and negative charge carriers with high mobilities along the polymer chain. Thin films of these conjugated polymers can be used in the preparation of optical devices such as light-emitting devices. These devices have numerous advantages over devices prepared using conventional semiconducting materials, including the possibility of wide area displays, low dc working voltages and simplicity of manufacture. Devices of this type are described in, for example, WO-A-90/13148, U.S. Pat. No. 5,512,654 and WO-A-95/06400.

Efficient and highly stable electroluminescent devices with low power consumption and which fulfill commercial requirements, have been prepared by a number of companies and academic research groups (see, for example, R. H. Friend et al., Nature 1999, 397, 12).

At their most basic, organic electroluminescent devices generally comprise an organic light emitting material which is positioned between a hole injecting electrode and an electron injecting electrode. The hole injecting electrode (anode) is typically a transparent tin-doped indium oxide (ITO)-coated glass substrate. The material commonly used for the electron injecting electrode (cathode) is a low work function metal such as calcium or aluminium.

The materials that are commonly used for the organic light emitting layer include conjugated polymers such as poly-phenylene-vinylene (PPV) and derivatives thereof (see, for example, WO-A-90/13148), polyfluorene derivatives (see, for example, A. W. Grice et al, Appl. Phys. Lett. 1998, 73, 629, WO-A-00/55927 and Bernius et al., Adv. Materials 2000, 12(23), 1737), polynaphthylene derivatives and polyphenanthrenyl derivatives; and small organic molecules such as aluminium quinolinol complexes (Alq3 complexes: see, for example U.S. Pat. No. 4,539,507) and quinacridone, rubrene and styryl dyes (see, for example, JP-A-264692/1988). The organic light emitting layer can comprise mixtures or discrete layers of two or more different emissive organic materials.

Typical device architecture is disclosed in, for example, WO-A-90/13148; U.S. Pat. No. 5,512,654; WO-A-95/06400; R. F. Service, Science 1998, 279, 1135; Wudl et al., Appl. Phys. Lett. 1998, 73, 2561; J. Bharathan, Y. Yang, Appl. Phys. Lett. 1998, 72, 2660; T. R. Hebner et al, Appl. Phys. Lett. 1998, 72, 519); and WO 99/48160; the contents of which references are incorporated herein by reference thereto.

Electroluminescent devices constructed from blended binary systems consisting of hole and electron-transporting organic and non-organic semiconductor materials have shown high external quantum efficiencies (number of photons emitted to electrons injected). Photoluminescence from semiconductor materials occurs by excitons radiatively decaying. Excitons are formed when a hole and an electron recombine within the material. It has been shown that efficient charge recombination takes place at the heterojunction between hole and electron transporting semiconductor materials. Ideally, an electroluminescent device should have an adequate thickness of photo-luminescent material within which photoluminescence takes place so that the percentage of injected charges used is maximised. In order to achieve high external quantum efficiency, the active material layer should consist of at least two components with distributed heterojunctions throughout the film, to aid charge recombination. It should have short and direct transportation paths to the recombination zone from each electrode, in order to maximise the rate of arrival of charges at the recombination sites. The anode should be capped with a hole transporting layer and the cathode with an electron-transporting layer, in order to reduce leakage current to a minimum. Furthermore, there should be a balance of hole and electron transportation from the electrodes to the recombination zone, for blends, in order to have the recombination zone in the middle of the active layer, away from either electrode, reducing exciton quenching close to either electrode, or in a layered structure, to reduce the build up of space charge, which increases the need for higher driving voltages.

It has been demonstrated that the performance of an electroluminescent device formed as a mixture of two polymers can be greatly enhanced by controlling the blend morphology (see Berggren et al, Nature 1994, 372, 444). This is achieved by altering the device preparation parameters (solution and substrate temperatures, spin-speeds, solvent saturated atmosphere and by using different solvents). However, significant loss mechanisms in these devices are due to leakage current, caused by percolation paths from cathode to anode within each component of the blend, an imbalance of the charge transportation of holes and electrons to the recombination sites, and a lack of short and direct transportation paths from each electrode to the recombination zone within the blend. It is therefore desirable to produce new electroluminescent devices comprising blended systems consisting of hole and electron-transporting organic or inorganic semiconductor materials having a large interfacial area between the semiconductor materials, creating a large recombination zone, and short and direct transportation paths from each electrode to the recombination zone.

Polymer brushes have been widely used in polymer physics and chemistry in order to understand the physical properties of polymers. For example, they have been used to control surface properties such as adhesion, friction, corrosion resistance and wettability (e.g. see K. R. Shull, J. Chem. Phys. 1991, 94(8), 5723-5738). However, they have not previously been incorporated within organic electronic devices such as photovoltaic devices and electroluminescent devices, nor has there ever been any suggestion that might have led the skilled person to believe that they might be of use for this purpose.

### SUMMARY OF THE INVENTION

It is an object of the present invention to provide novel organic, or inorganic organic hybrid, electronic devices having a blend of at least two semiconducting materials at least one of which is an organic semiconducting material, in which there is a large interfacial area between said semiconductor materials and direct transportation paths from each electrode to said interfaces.

It is a further object of the present invention to provide a process for the manufacture of these novel organic electronic devices.

Thus, in a first aspect of the present invention there is provided an organic electronic device comprising at least two electrodes and a semiconducting layer comprising a mixture of at least one hole-transporting semiconducting material and at least one electron-transporting semiconducting material, wherein at least one of said semiconducting materials is in the form of semiconducting polymer brushes which are attached to the surface of at least one of said electrodes and are in contact with at least one of said other semiconducting materials.

The semiconducting polymer brushes used in the devices of the present invention give excellent device characteristics as there is a large interfacial area between said polymer brushes and the other semiconducting material (or materials) with which they are in contact and they provide direct transport paths for electrons and holes to or from the electrodes to which they are attached. Current density perpendicularly through the polymer brush film has been found to be up to 30 times greater than through a conventional spin-coated amorphous film of the same polymer. Contact between the semiconducting polymer brushes attached to the electrode and the other semiconducting material can be, for example, by intercalation of said second semiconducting material with said semiconducting polymer brushes, by growth of said second semiconducting material as semiconducting polymer brushes in the gaps between said first semiconducting polymer brushes to give an interpenetrating mixed polymer network and by the polymerisation of a second, different monomer from the end of said first polymer brushes to give block co-polymer brushes having a bi-layer structure with direct covalent bonds between the two semiconducting components.

The organic electronic devices of the present invention are devices that comprise at least two electrodes and a semiconducting layer which is capable of transporting charges (electrons or holes) to or from said electrodes, said semiconducting layer comprising a mixture of at least one hole-transporting semiconducting material and at least one electron-transporting semiconducting material at least one of which is an organic semiconducting material. Suitable examples of said devices include electroluminescent devices, photovoltaic devices, field effect transistors and liquid crystal devices. Of these, photovoltaic devices and electroluminescent devices are particularly preferred.

For good charge transport properties and a large interfacial area with the other semiconducting component(s), the polymer brushes attached to the electrode surfaces of the devices of the present invention should be as long as possible. Preferably, the average length of the polymer brushes should be from 1 nm to 1 μm, and most preferably the average length of the polymer brushes should be at least 40 nm.

The semiconducting polymer brushes in the devices of the present invention comprise any semiconducting polymer that can be grown as brushes from the surface of an electrode material, or tethered to the surface of an electrode material. Examples of suitable semiconducting materials that could be grown as semiconducting polymer brushes from an electrode surface include: poly-phenylene-vinylene (PPV) and derivatives thereof (see, for example, WO-A-90/13148), polyfluorene derivatives (see, for example, A. W. Grice, D. D. C. Bradley, M. T. Bernius, M. Inbasekaran, W. W. Wu, and E. P. Woo, Appl. Phys. Lett. 1998, 73, 629, WO-A-00/55927 and Bernius et al., Adv. Materials, 2000, 12, No. 23, 1737), polynaphthylene derivatives, polyindenofluorene derivatives, polyphenanthrenyl derivatives and poly(acrylate) derivatives having activating pendant side chains (see, for example, M. Stolka, D. M. Pai, D. S. Renfer, and J. F. Yanus, Journal of Polymer Science Part A—Polymer Chemistry, 1983, 21, 969; and M. Tamada, H. Koshikawa, F. Hosi, T. Suwa, H. Usui, A. Kosaka, H. Sato, Polymer. 1999, 40(11), 3061-3067).

Specific examples of semiconducting polymeric materials that could be grown as semiconducting polymer brushes from the surface of an electrode, or tethered to the surface of an electrode material, include polymers which include the following conjugated units of formulae (I), (VIII), (IX), (X), (XI), (XII), (XIII), (XIV) or (XV). These polymers can be homopolymers or can contain two or more different conjugated units, e.g. alternating AB copolymers and terpolymers, and statistical copolymers and terpolymers. 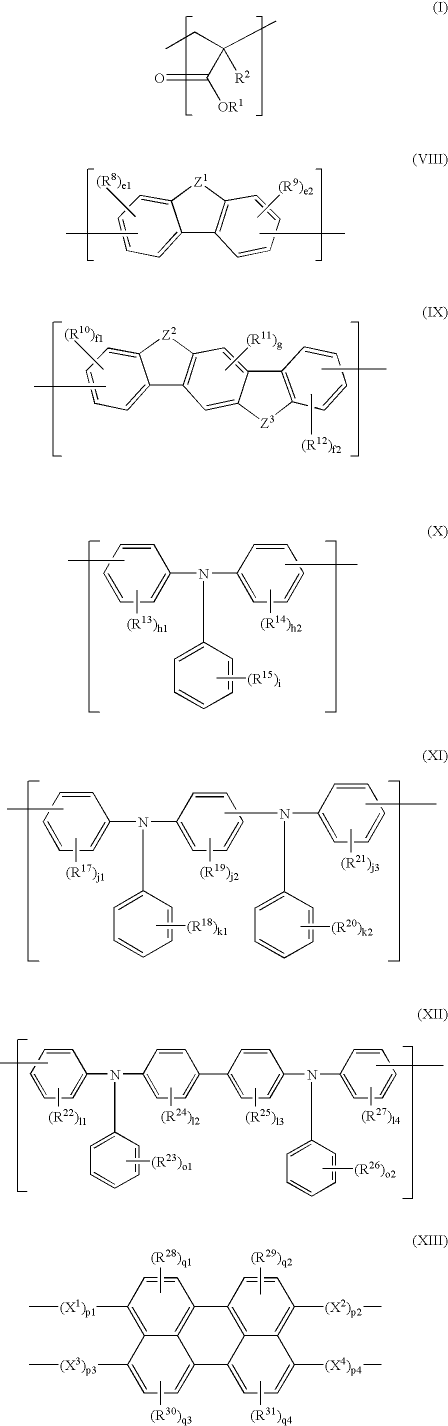 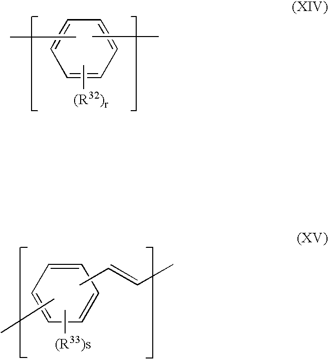
wherein:

R¹ is a group of formula —(CH₂)ₘ—X—Y wherein

m is 0 or an integer of from 1 to 6,

X is a group of formula (X), (XI), (XII), (XIII), (XIV) or (XV) as defined above or a group of formula (II) or (III) as defined below 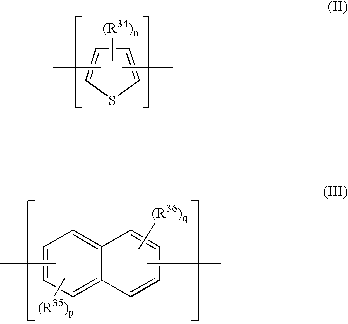
wherein

n is 0, 1 or 2,

p and q are the same or different and each is 0 or an integer of from 1 to 3, and

each of R³⁴, R³⁵ and R³⁶ is the same or different and is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is selected from the group consisting of hydroxy groups, alkyl groups as defined below, haloalkyl groups as defined below, alkoxy groups as defined below, alkoxyalkyl groups as defined below, aryl groups as defined below, aryloxy groups as defined below, aralkyl groups as defined below, amino groups, alkylamino groups the alkyl moiety of which is as defined below, dialkylamino groups wherein each alkyl moiety is the same or different and is as defined below, aralkyloxy groups the aralkyl moiety of which is as defined below and haloalkoxy groups comprising an alkoxy group as defined below which is substituted with at least one halogen atom,

or, where n, p or q is an integer of 2, the 2 groups R³⁴, R³⁵ or R³⁶ respectively may, together with the ring carbon atoms to which they are attached, form an aryl group as defined below or a heterocyclic group having from 5 to 7 ring atoms, one or more of said ring atoms being a heteroatom selected from the group consisting of nitrogen, oxygen and sulfur atoms, and

Y is selected from the group consisting of a hydrogen atom, R³⁷, NHR³⁸ and NR³⁸R³⁹, wherein

R³⁷ is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is as defined above, and

each of R³⁸ and R³⁹ is the same or different and is selected from the group consisting of aryl groups as defined below and aralkyl groups as defined below;

R² is selected from the group consisting of group consisting of hydrogen atoms, alkyl groups as defined below, haloalkyl groups as defined below and alkoxy groups as defined below;

each of R⁸ to R¹⁵ and R¹⁷ to R³³ is the same or different and is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is as defined above,

or, where r or s is an integer of 2, the 2 groups R³² or R³³ respectively may, together with the ring carbon atoms to which they are attached, form a heterocyclic group having from 5 to 7 ring atoms, one or more of said ring atoms being a heteroatom selected from the group consisting of nitrogen, oxygen and sulfur atoms;

each of Z¹, Z² and Z³ is the same or different and is selected from the group consisting of O, S, SO, SO₂, NR³, N⁺(R^{3′})(R^{3″}), C(R⁴)(R⁵), Si(R^{4′})(R^{5′}) and P(O)(OR⁶), wherein R³, R^{3′} and R^{3″} are the same or different and each is selected from the group consisting of hydrogen atoms, alkyl groups as defined below, haloalkyl groups as defined below, alkoxy groups as defined below, alkoxyalkyl groups as defined below, aryl groups as defined below, aryloxy groups as defined below, aralkyl groups as defined below, and alkyl groups as defined below which are substituted with at least one group of formula —N⁺(R⁷)₃ wherein each group R⁷ is the same or different and is selected from the group consisting of hydrogen atoms, alkyl groups as defined below and aryl groups as defined below, R⁴, R⁵, R^{4′} and R^{5′} are the same or different and each is selected from the group consisting of hydrogen atoms, alkyl groups as defined below, haloalkyl groups as defined below, alkoxy groups as defined below, halogen atoms, nitro groups, cyano groups, alkoxyalkyl groups as defined below, aryl groups as defined below, aryloxy groups as defined below and aralkyl groups as defined below or R⁴ and R⁵ together with the carbon atom to which they are attached represent a carbonyl group, and R⁶ is selected from the group consisting of hydrogen atoms, alkyl groups as defined below, haloalkyl groups as defined below, alkoxyalkyl groups as defined below, aryl groups as defined below, aryloxy groups as defined below and aralkyl groups as defined below;

each of X¹, X², X³ and X⁴ is the same or different and is selected from:

arylene groups which are aromatic hydrocarbon groups having from 6 to 14 carbon atoms in one or more rings which may optionally be substituted by at least one substituent selected from the group consisting of nitro groups, cyano groups, amino groups, alkyl groups as defined below, haloalkyl groups as defined below, alkoxyalkyl groups as defined below, aryloxy groups as defined below and alkoxy groups as defined below;
straight or branched-chain alkylene groups having from 1 to 6 carbon atoms;
straight or branched-chain alkenylene groups having from 2 to 6 carbon atoms; and
straight or branched-chain alkynylene groups having from 1 to 6 carbon atoms; or
X¹ and X² together and/or X³ and X⁴ together can represent a linking group of formula (V) below:

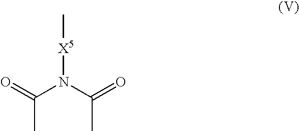

wherein X⁵ represents an arylene group which is an aromatic hydrocarbon group having from 6 to 14 carbon atoms in one or more rings which may optionally be substituted by at least one substituent selected from the group consisting of nitro groups, cyano groups, amino groups, alkyl groups as defined below, haloalkyl groups as defined below, alkoxyalkyl groups as defined below, aryloxy groups as defined below and alkoxy groups as defined below;

each of e1, e2, f1 and f2 is the same or different and is 0 or an integer of 1 to 3;

each of g, q1, q2, q3 and q4 is the same or different and is 0, 1 or 2;

each of h1, h2, j1, j2, j3, l1, l2, l3, l4, r and s is the same or different and is 0 or an integer of 1 to 4;

each of i, k1, k2, o1 and o2 is the same or different and is 0 or an integer of 1 to 5; and

each of p1, p2, p3 and p4 is 0 or 1;

the alkyl groups above are straight or branched-chain alkyl groups having from 1 to 20 carbon atoms;

the haloalkyl groups above are alkyl groups as defined above which are substituted with at least one halogen atom;

the alkoxy groups above are straight or branched-chain alkoxy groups having from 1 to 20 carbon atoms;

the alkoxyalkyl groups above are alkyl groups as defined above which are substituted with at least one alkoxy group as defined above; and

the aryl group above and the aryl moiety of the aralkyl groups (which have from 1 to 20 carbon atoms in the alkyl moiety) and the aryloxy groups above is an aromatic hydrocarbon group having from 6 to 14 carbon atoms in one or more rings which may optionally be substituted with at least one substituent selected from the group consisting of nitro groups, cyano groups, amino groups, alkyl groups as defined above, haloalkyl groups as defined above, alkoxyalkyl groups as defined above and alkoxy groups as defined above.

The particularly preferred semiconducting polymers brushes for use in photovoltaic and electroluminescent devices of the present invention include homopolymeric brushes which comprise groups of formulae (I), (VIII), (IX), (X), (XIV) or (XV), examples of which include poly(4-diphenylaminobenzyl acrylate), PPV, poly(2-methoxy-5-(2′-ethyl)hexyloxy-phenylene-vinylene) (“MEH-PPV”), PPV derivatives such as dialkoxy and dialkyl derivatives, polyfluorene derivatives and related copolymers; and the most preferred polymers include poly(4-diphenylaminobenzyl acrylate), PPV, MEH-PPV, poly(2,7-(9,9-di-n-hexylfluorene)), poly(2,7-(9,9-di-n-octylfluorene)), poly(2,7-(9,9-di-n-octylfluorene)-(1,4-phenylene-((4-sec-butylphenyl)imino)-1,4-phenylene)) (“TFB”), and poly(2,7-(9,9-di-n-octylfluorene)-3,6-benzothiadiazole) (“F8BT”).

The other semiconducting material (or materials) that is in contact with the polymer brushes of the devices of the present invention can be an organic or inorganic semiconducting material. The organic semiconducting material can be a semiconducting polymeric material or a semiconducting small organic molecule, preferably a semiconducting polymeric material. The inorganic semiconducting material can be a semiconducting nanoparticle, particularly a semiconducting nanocrystalline material such as semiconducting nanocrystals of cadmium selenide, lead selenide, zinc selenide, cadmium sulphide or zinc sulphide [see, for example, Peng, Z. A.; Peng, X. G. J. Am. Chem. Soc. 124, 3343 (2002); Murray, C. B. et al, J. Am. Chem. Soc. 115, 8706 (1993); and Katari, J. E. B. et al, J. Phys. Chem. 98, 4109 (1994)]. Cadmium selenide nanocrystals are particularly preferred as they are good electron acceptors and have high electron mobility.

The choice of semiconducting material will vary depend upon factors such as the nature of the organic electronic device, and the identity and properties of the semiconducting polymer brushes attached to the electrode surface. Thus, for example, if the semiconducting polymer brushes are hole-transporting polymer brushes that are attached to the anode of a photovoltaic device, then the other semiconducting material (or materials) that are in contact with said polymer brushes must be electron-transporting to provide a path for the electrons to the cathode.

Preferred examples of the other semiconducting material that is in contact with the semiconducting polymer brushes include: conjugated polymers such as polyphenylene-vinylene (PPV) and derivatives thereof (see, for example, WO-A-90/13148), polyfluorene derivatives (see, for example, A. W. Grice, D. D. C. Bradley, M. T. Bernius, M. Inbasekaran, W. W. Wu, and E. P. Woo, Appl. Phys. Lett. 1998, 73, 629, WO-A-00/55927 and Bernius et al., Adv. Materials, 2000, 12, No. 23, 1737), polynaphthylene derivatives, polyindenofluorene derivatives and polyphenanthrenyl derivatives; small organic molecules such as aluminium quinolinol complexes (Alq₃ complexes: see, for example U.S. Pat. No. 4,539,507), perylene and derivatives thereof, complexes of transition metals, lanthanides and actinides with organic ligands such as TMHD (see WO-A-00/26323) and quinacridone, rubrene and styryl dyes (see, for example, JP-A-264692/1988); the contents of which references are incorporated herein by reference thereto; and semiconducting cadmium selenide nanocrystals (see, for example, Peng, Z. A.; Peng, X. G. J. Am. Chem. Soc. 2002, 124, 3343-, the contents of which are incorporated herein by reference thereto).

Specific examples of preferred semiconducting polymeric materials that are in contact with the semiconducting polymer brushes include polymers which include the conjugated units of formulae (VIII), (IX), (X), (XI), (XII), (XIII), (XIV) or (XV) as defined above. These polymers can be homopolymers or can contain two or more different conjugated units, e.g. alternating AB copolymers and terpolymers, and statistical copolymers and terpolymers.

The particularly preferred semiconducting polymers for use in photovoltaic and electroluminescent devices of the present invention include homopolymers, copolymers and terpolymers which comprise groups of formulae (VIII), (IX), (X), (XIV) or (XV), examples of which include poly(4-diphenylaminobenzyl acrylate), PPV, poly(2-methoxy-5-(2′-ethyl)hexyloxy-phenylene-vinylene) (“MEH-PPV”), PPV derivatives such as dialkoxy and dialkyl derivatives, polyfluorene derivatives and related copolymers; and the most preferred polymers include poly(4-diphenylaminobenzyl acrylate), PPV, MEH-PPV, poly(2,7-(9,9-di-n-hexylfluorene)), poly(2,7-(9,9-di-n-octylfluorene)), poly(2,7-(9,9-di-n-octylfluorene)-(1,4-phenylene-((4-sec-butylphenyl)-imino)-1,4-phenylene)) (“TFB”), and poly(2,7-(9,9-di-n-octylfluorene)-3,6-benzo-thiadiazole) (“F8BT”). The most preferred semiconducting small organic molecules include Alq₃ complexes and perylene and derivatives thereof. The particularly preferred semiconducting inorganic materials are semiconducting cadmium selenide nanocrystals.

At their most basic, the organic electronic devices such as organic photovoltaic devices and organic electroluminescent devices generally comprise semiconducting polymer brushes which are attached to one of the electrodes of said devices which are in contact with at least one further semiconducting material, one of the materials being hole transporting and the other being electron transporting. In organic photovoltaic devices and organic electroluminescent devices of the present invention, the anode is typically a transparent tin-doped indium oxide (ITO)-coated glass substrate. Zirconium-doped indium oxide (Applied Physics Letters, 78 (8) 1050 (2001), Kim, H et al) and aluminium-doped zinc oxide (Applied Physics Letters, 76 (3) 259 (2000), Kim H et al) films have also been used as the anode. Alternatives as the anode material that have also been tried include: titanium nitride [Advanced Materials, 11 (9) 727 (1999), Adamovich V, et al.]; high work function transparent conducting oxides including Ga—In—Sn—O and Zn—In—Sn—O [Advanced Materials, 13 (19) 1476 (2001), Cui, J., et al]; polymeric materials such as polystyrenesulfonic acid-doped polyaniline [Applied Physics Letters, 70 (16) 2067 (1997), Carter S. A et al, and Applied Physics Letters, 64 (10) 1245 (1994) Yang Y et al.].

The cathode can be formed from any material typically used for this purpose in electroluminescent devices and photovoltaic devices. Examples of suitable materials include low work function metals such as potassium, lithium, sodium, magnesium, lanthanum, cerium, calcium, strontium, barium, aluminium, silver, indium, tin, zinc and zirconium, and binary or ternary alloys containing such metals. Of these, successive layers of aluminium and calcium and aluminium-calcium alloys containing from 1 to 20% by weight of calcium are preferred.

Typical device architecture for electroluminescent devices is disclosed in, for example, WO-A-90/13148; U.S. Pat. No. 5,512,654; WO-A-95/06400; R. F. Service, Science 1998, 279, 1135; Wudl et al., Appl. Phys. Lett. 1998, 73, 2561; J. Bharathan, Y. Yang, Appl. Phys. Lett. 1998, 72, 2660; T. R. Hebner et al, Appl. Phys. Lett. 1998, 72, 519); and WO 99/48160; the contents of which references are incorporated herein by reference thereto. Typical device architecture for photovoltaic devices is disclosed in, for example R. H. Friend at al., Nature, 1998, 395, 257; C. J. Brabec et al., App. Phys. Lett. 2000, 78, 841; A. C. Arias et al., Macromolecules, 2001, 34, 6005; H. J. Snaith et al., Nano. Lett. 2002, 2, 1353; A. C. Arias et al., Appl. Phys. Lett., 2002, 80, 1695; and J. R. Heflin et al., Appl. Phys. Lett., 2002, 4607; the contents of which references are incorporated herein by reference thereto.

The deposition of high work function organic materials on the anodes of the devices of the present invention, such as poly(styrene sulfonate)-doped poly(3,4-ethylene dioxythiophene) (PEDOT/PSS), N,N′-diphenyl-N,N′-(2-naphthyl)-(1,1′-phenyl)-4,4′-diamine (NBP) and N,N′-bis(3-methylphenyl)-1,1′-biphenyl-4,4′-diamine (TPD), or high work function inorganic materials on the anodes of the devices of the present invention, such as aluminium oxide, provides “hole transport” layers which facilitates, for example, the hole injection into the light emitting layer of the electroluminescent devices of the present invention. These layers are effective in increasing the number of holes introduced into the light emitting layer of electroluminescent devices and increasing the number of holes collected at the anode of the photovoltaic devices of the present invention and/or decreasing the number of electrons collected at the anode of the photovoltaic devices of the present invention.

In some devices, an electron transport layer may also be provided between the cathode and the semiconducting layer (e.g. suitable compounds include oxides of alkali metals, alkaline earth metals or lanthanoid elements having a work function of up to 4 eV, such as those disclosed in EP-A-1009045). These facilitate, for example, the electron injection into the light emitting layer of the electroluminescent devices of the present invention so that they transport electrons stably from the electron injecting layer and they obstruct holes. Particularly preferred are strontium oxide, magnesium oxide, calcium oxide, lithium oxide, rubidium oxide, potassium oxide, sodium oxide and cesium oxide.

In the devices of the present invention, the semiconducting polymer brushes are “attached” to the surface of at least one of the electrodes of said device. By this we mean that the semiconducting polymer brushes are either:

(i) directly bonded to atoms in the surface of said electrode;

(ii) bonded to atoms in the surface of a hole transport layer or electron transport layer coated on said electrode; or

(ii) bonded to the end of the molecules in a self-assembled monolayer (SAM) of, for example, thiol or siloxane molecules adsorbed on or bonded to the surface of said electrode or said hole transport layer or electron transport layer (see, for example, Jones et al, Langmuir 2002, 18, 1265-1269)

The photovoltaic devices and electroluminescent devices of the present invention may typically have the stacked configuration of substrate (e.g. glass), an anode, semiconducting polymer brushes attached to the surface of said anode, a further semiconducting material (or materials) intercalated with said polymer brushes, and a cathode on top of the further semiconducting material. Alternatively, the device may have the inversely stacked configuration of substrate, a cathode, semiconducting polymer brushes attached to the surface of said cathode, a further semiconducting material (or materials) intercalated with said polymer brushes, and an anode on top of the further semiconducting material.

In a further aspect of the present invention, there is provided a process for the manufacture of an organic electronic device comprising at least two electrodes and a semiconducting layer comprising a mixture of at least one hole-transporting semiconducting material and at least one electron-transporting semiconducting material, said process comprising:

(a) coating a substrate with a material to form one of the electrodes;

(b) optionally coating the electrode thus formed with a self-assembled monolayer end-capped with an initiator group or a self-assembled monolayer with the capability of forming a free radical;

(c) bringing the electrode, optionally coated with the self-assembled monolayer produced in step (b), into contact with a solution of a monomer under conditions suitable for the growth of polymer brushes comprising said monomer unit from the surface of said electrode;

(d) treating the product of step (c) in such a way as to produce a product in which the polymer brushes are in contact with at least one further semiconducting material; and

(e) coating a material on the top surface of the product of step (d) to form the further electrode.

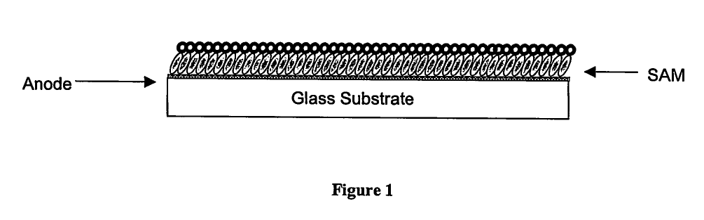

The organic photovoltaic devices and organic electroluminescent devices of the present invention are typically manufactured by first coating the anode material on a substrate (e.g. glass), typically by sputtering or evaporation. The devices can be fabricated with a semi-transparent anode, for example indium tin oxide. Optionally a self-assembled monolayer (SAM) of, for example, thiol or siloxane molecules is deposited on the surface of said anode. The molecules of the SAM are end capped with an initiator group (e.g. a bromine atom) that is on the upper surface of the SAM (see FIG. 1) that can react with the monomer units that form the start of growing semiconducting polymer brush. Optionally the molecules of the SAM may be of the form that they are not end capped with an initiator group, and instead produce a free radical upon further treatment that can react with the monomer units that form the start of growing semiconducting polymer brush. An example of such SAM is 2-2′-azo-bis-isobutyrylnitrile (AIBN) and an example of further treatment would be heating. The typical thickness of the SAM is from 1 to 10 nm, as measured by ellipsometry.

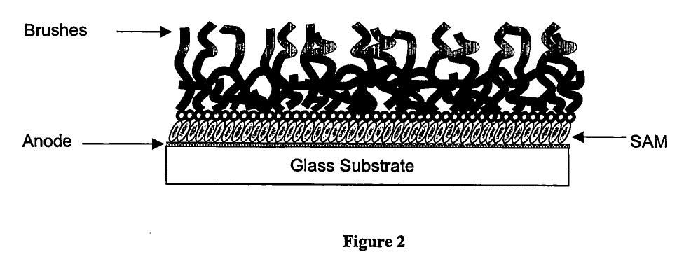

A monomer solution is then precipitated on the anode (that has optionally been coated with a SAM), resulting in the monomer polymerising after initiation by reaction with atoms in the surface of the anode itself or with the initiator group at the end of the SAM, or with the free radical at the end of the SAM to give semiconducting polymer brushes attached to the anode surface. These brushes can range from 1 nm to over 1 micron in length (see FIG. 2). The polymer brushes are produced by surface-initiated polymerisation of monomers. Examples of suitable “living” polymerisation techniques to grow polymer brushes from the surface include cationic (Jordan et al, J. Am. Chem. Soc. 1998, 120, 243), anionic (Jordan et al, J. Am. Chem. Soc. 1999, 121, 1016), ring-opening (Weck et al, J. Am. Chem. Soc. 1999, 121, 4088), nitroxide-mediated (Husemann et al, Macromolecules 1999, 32, 1424) and atom transfer radical polymerisation (ATRP) (Huang and Wirth, Macromolecules 1999, 32, 1694).

The substrates, with the polymer brushes attached, then have at least one other semiconducting component coated upon them. The coating method can be any technique suitable for such a coating process, typical examples including spin coating, blade coating, drop casting or inkjet printing. The resulting structure comprises semiconducting polymer brushes which are intercalated with the further semiconducting material(s) coated upon them.

The cathode material such as calcium, aluminium or magnesium is then coated onto the top of the active layer. Typically, either an evaporation process or a sputtering process is used.

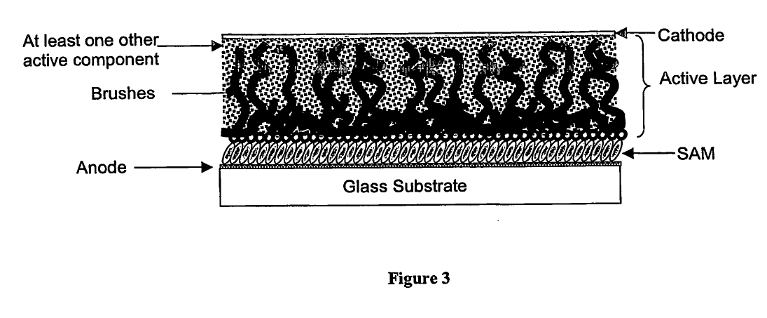

The resulting structure of the active semiconducting layer is of one material (the polymer brushes) predominantly in contact with the anode. This material interpenetrates the at least one other active semiconducting component (or components), which is predominantly in contact with the cathode (see FIG. 3).

In the photovoltaic devices of the present invention, this structure provides distributed heterojunctions to aid charge separation, and direct transportation paths to each electrode within each component of the active layer to maximise charge extraction. In the electroluminescent devices of the present invention, this structure provides a large interfacial area between the two components, to aid charge recombination, and short and direct transportation paths to the recombination zone within each component of the active layer. It also may provide a capping of the anode with hole transporting material and the cathode with electron transporting material minimising the leakage current.

Optionally, high work function organic materials may be deposited on the anodes of the devices of the present invention, such as poly(styrene sulfonate)-doped poly(3,4-ethylene dioxythiophene) (PEDOT/PSS), N,N′-diphenyl-N,N′-(2-naphthyl)-(1,1′-phenyl)-4,4′-diamine (NBP) and N,N′-bis(3-methylphenyl)-1,1′-biphenyl-4,4′-diamine (TPD), or high work function inorganic materials on the anodes of the devices of the present invention, such as aluminium oxide providing “hole transport” layers. The semiconducting polymer brushes are then grown from the surface of said hole transport layer. It may be necessary to first treat the surface of the hole transport layer to produce reactive groups on said surface that can either react with the monomer units forming the polymer brushes or be treated to form a SAM thereon. In the case of PEDOT/PSS, for example, it may be treated with oxygen plasma to give dangling hydroxyl groups that can then react with siloxane molecules having an end-capping initiator group.

In an alternative reverse-stacked configuration, the substrate can first be coated with a cathode material, semiconducting polymer brushes can be attached to the surface of said cathode in a similar manner to that described above for attachment of polymer brushes to the anode, a further semiconducting material (or materials) is intercalated with said polymer brushes, and an anode is then deposited on top of the further semiconducting material.

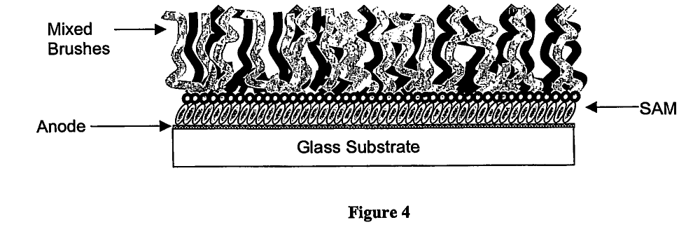

Alternatively the active layer can comprise mixed polymer brushes. Mixed polymer brushes can be grown from the electrode surface or the self-assembled monolayer by first polymerising one monomer and then polymerising a second. This results in molecularly mixed brushes. If both brushes have different functional groups, for example a poly(acrylate) backbone with triarylamine pendant side chains and a poly(acrylate) backbone with perylene pendant side chains, then an interpenetrating network with close contact would be obtained, obviating the need for a second layer to be percolated through the first layer of brushes (see FIG. 4).

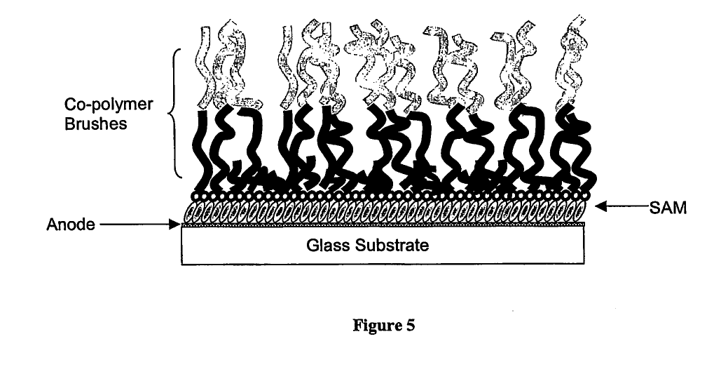

In another alternative, block co-polymer brushes can be grown from the pre-prepared substrates, by first polymerising one monomer from the surface of the electrode or from the self assembled monolayer and then polymerising a second monomer from the end of the first polymer brush. If the bottom block is hole conducting and the top block is electron conducting, this will result in a bi-layer structure with molecular contact between the two components (see FIG. 5). In electroluminescent devices, the length of each block can be tailored with respect to the intrachain mobility of the polymer, such that the holes and electrons meet at the hetero junction of each block copolymer at the same time.

Co-polymerization can be used to grow long polymer brushes consisting of different polymers. A layer of semiconducting material can be percolated through the layer of brushes to obtain a similar structure to that shown in FIG. 3, apart from having co-polymer brushes which conduct one species of charge. In photovoltaic devices, if the different polymers within the brushes have a range of absorption spectra over the solar spectrum, then the final device can be more efficient at converting photons to charges over the solar spectrum. In electroluminescent devices, the colour of the emitted light can be tailored by having different lengths of each block, which emit at different parts of the spectrum. If the electric field dependence of the mobility is vastly different between the electron and hole transporting components, then the recombination zone can be shifted in the device by varying the operating voltage. This will result in the colour of the emitted light being tuneable by varying the operating voltage.

In a further aspect of the present invention, there is provided an organic electronic device comprising at least two electrodes and a semiconducting layer comprising at least one hole-transporting semiconducting material or at least one electron-transporting semiconducting material, wherein said at least one semiconducting material is in the form of semiconducting polymer brushes which are attached to the surface of at least one of said electrodes. According to this aspect, the device preferably is a field effect transistor.

In a further aspect, there is provided a process for the manufacture of an organic electronic device comprising at least two electrodes and a semiconducting layer comprising at least one hole-transporting semiconducting material or at least one electron-transporting semiconducting material, said process comprising:

(a) coating a substrate with a material to form one of the electrodes;

(b) optionally, but preferably, coating the electrode thus formed with a layer of an electronically insulating material;

(c) optionally coating the electrode thus formed in (a), or following optional step (b), with a self-assembled monolayer end-capped with an initiator group or a self-assembled monolayer with the capability of forming a free radical;

(d) bringing the electrode, optionally coated with the self-assembled monolayer produced in step (c), into contact with a solution of a monomer under conditions suitable for the growth of polymer brushes comprising said monomer unit from the surface of said electrode;

(e) coating a material on the top surface of the product of step (d) to form the further electrode.

The present invention may be further understood by consideration of the following examples, with reference to the following drawings in which:

FIG. 1 shows a schematic representation of an anode coated glass substrate with self-assembled monolayer adsorbed or bonded to the surface, the light grey oblong part representing the thiol or siloxane molecules of the SAM, and the black circles represent the initiator end group;

FIG. 2 shows a schematic representation of polymer brushes grown from the pre-prepared substrate shown in FIG. 1;

FIG. 3 shows a schematic representation of the structure of a photovoltaic device or electroluminescent device of the present invention, the dotted region representing a second semiconducting material intercalated with the semiconducting polymer brushes;

FIG. 4 shows a schematic representation of the structure of a photovoltaic device or electroluminescent device having a mixed brush layer attached to a pre-prepared substrate, the black brushes representing one active semiconducting component and the grey brushes representing at least one other active semiconducting component;

FIG. 5 shows a schematic representation of the structure of a photovoltaic device or electroluminescent device having a block co-polymer brush layer attached to a pre-prepared substrate, the black brushes representing one active semiconducting component and the grey brushes representing at least one other active semiconducting component grown from the end of the first component;

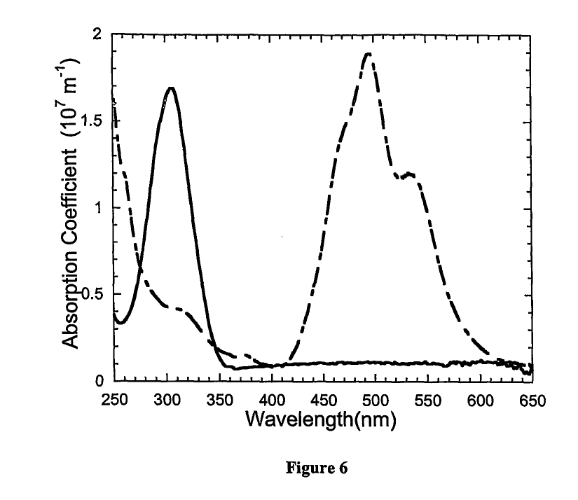

FIG. 6 shows a plot of absorption coefficient against wavelength of poly(4-diphenylaminobenzyl acrylate) (solid line) and perylene (dotted line);

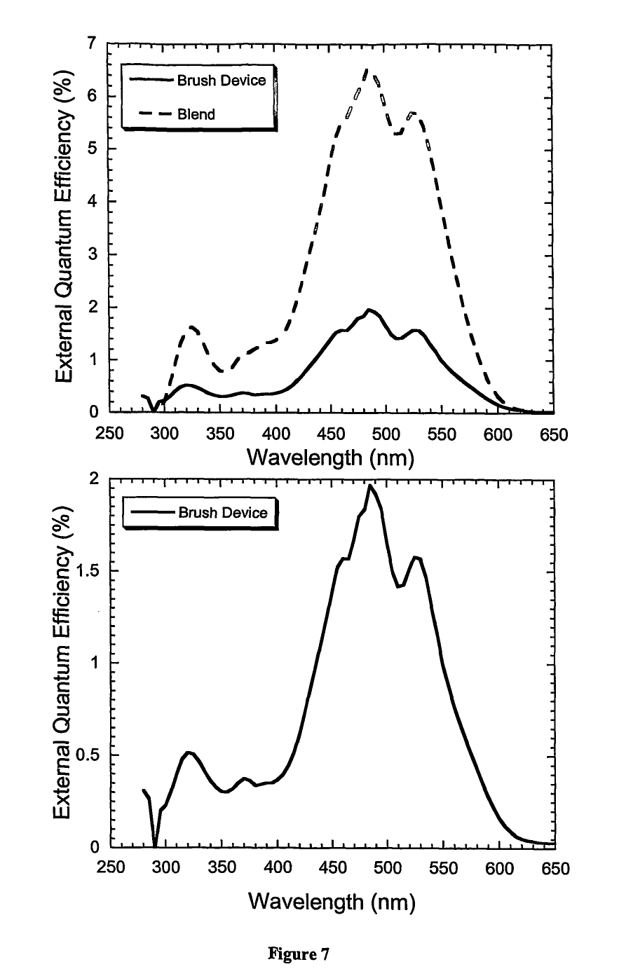

FIG. 7 shows external quantum efficiency spectra for a polymer blend photovoltaic device having a semiconducting layer comprising poly(4-diphenylaminobenzyl acrylate) and perylene (dotted line), and a polymer brush photovoltaic device of the present invention having poly(4-diphenylaminobenzyl acrylate) brushes intercalated with perylene (solid line);

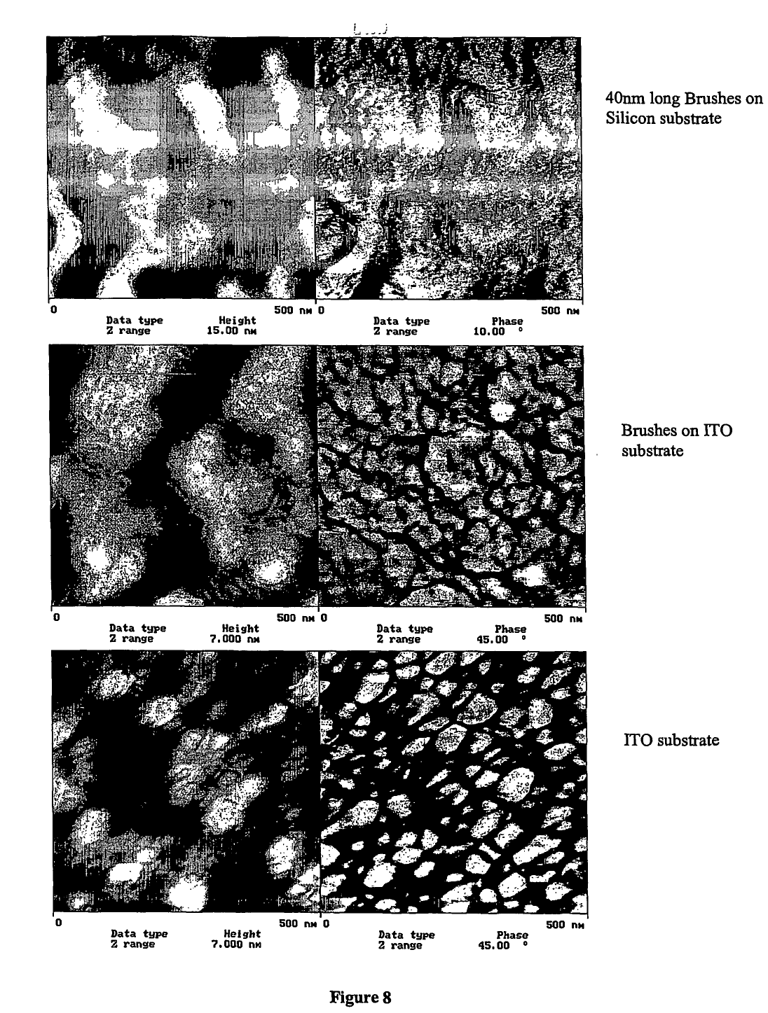

FIG. 8 shows an AFM spectrum image of a polymer brush film grown from an ITO substrate, which was subsequently used for a polymer brush photovoltaic device of the present invention having poly(4-diphenylaminobenzyl acrylate) brushes intercalated with perylene and comparative spectra for a complete covering of brushes grown from a silicon substrate and a clean ITO substrate.

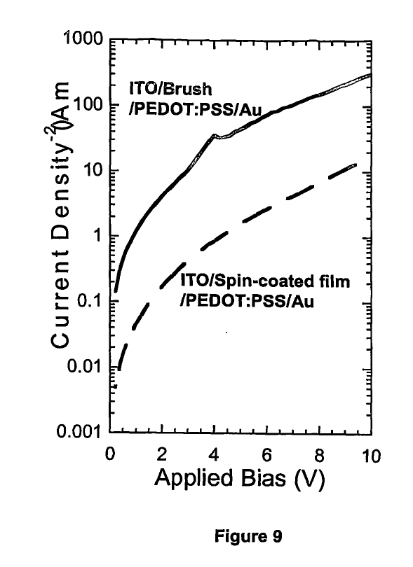

FIG. 9 shows the current-voltage characteristics of a poly(4-diphenylaminobenzyl acrylate) brush film of the present invention within a device structure; SAM modified ITO substrate/Polymer brush film/PEDOT:PSS spin-coated cathode/Gold contact. FIG. 9 also shows the current-voltage characteristics of a conventional spin-coated film of poly(4-diphenylaminobenzyl acrylate) in the device structure ITO substrate/Spin-coated polymer film/PEDOT:PSS spin-coated cathode/Gold contact.

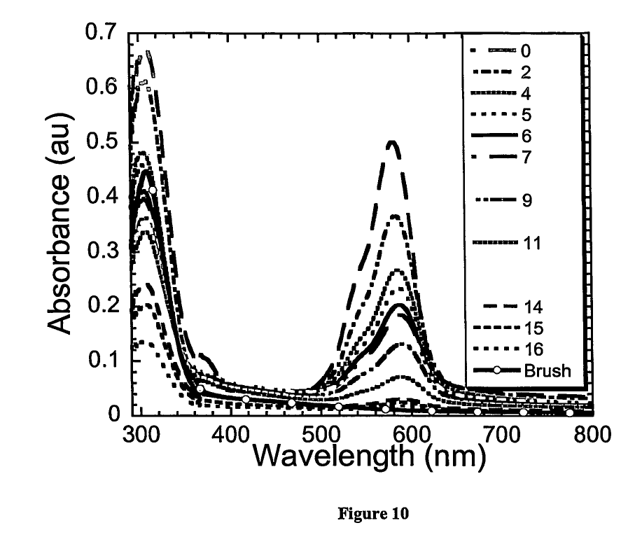

FIG. 10 shows the Ultraviolet-Visable (UV-vis) absorption spectrum for poly(4-diphenylaminobenzyl acrylate) brush film grown from modified ITO and poly(4-diphenylaminobenzyl acrylate) brush film grown from modified ITO coated with rhodamine dye, before and after increments of surface ablation with oxygen plasma. The number in the key corresponds to time of ablation in minutes; one minute corresponds to approximately 5 nm of film removed.

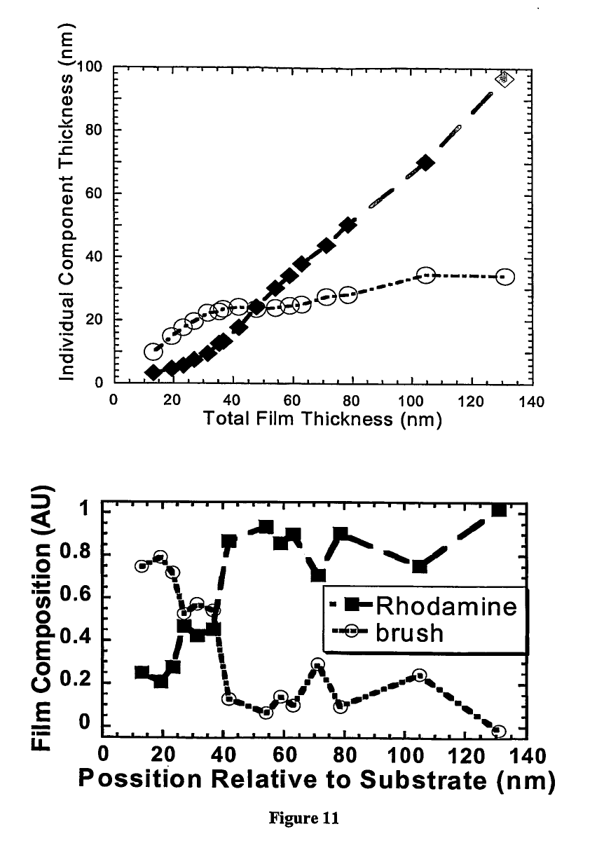

FIG. 11 shows the film composition as a function of position from ITO substrate. FIG. 11 also shows the relative quantity of each material (Polymer brush and rhodamine) as a function of film thickness, as calculated from FIG. 10.

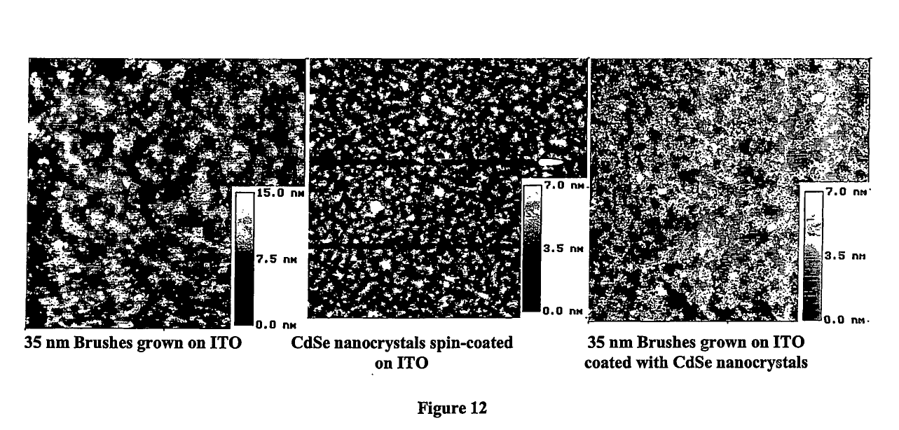

FIG. 12 shows the AFM images of a poly(4-diphenylaminobenzyl acrylate) brush film grown from a SAM modified ITO substrate, a cadmium selenide nanoncrystal film spin-coated on an ITO substrate, and a poly(4-diphenylaminobenzyl acrylate) brush film (grown from a modified ITO substrate) coated with cadmium selenide nanocrystals.

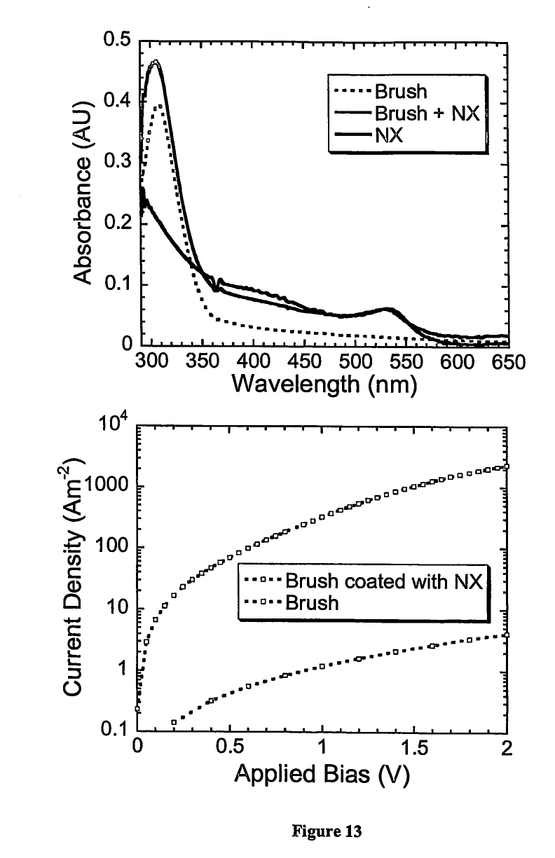

FIG. 13 shows the UV-vis absorption spectra for a 45 nm thick poly(4-diphenylaminobenzyl acrylate) brush film grown from a SAM modified ITO substrate, a 25 nm cadmium selenide nanocrystal film spin-coated on an ITO substrate, and a 45 nm thick poly(4-diphenylaminobenzyl acrylate) brush film (grown from a modified ITO substrate) coated with cadmium selenide nanocrystals. FIG. 13 also shows the current-voltage characteristics of a brush diode comprising: SAM modified ITO anode/a 45 nm thick poly(4-diphenylaminobenzyl acrylate) brush film (grown from the SAM modified ITO anode/PEDOT:PSS/gold and a photovoltaic device comprising: SAM modified ITO anode/45 nm thick poly(4-diphenylaminobenzyl acrylate) brush film (grown from the SAM modified ITO anode) coated with cadmium selenide nanocrystals/aluminium cathode.

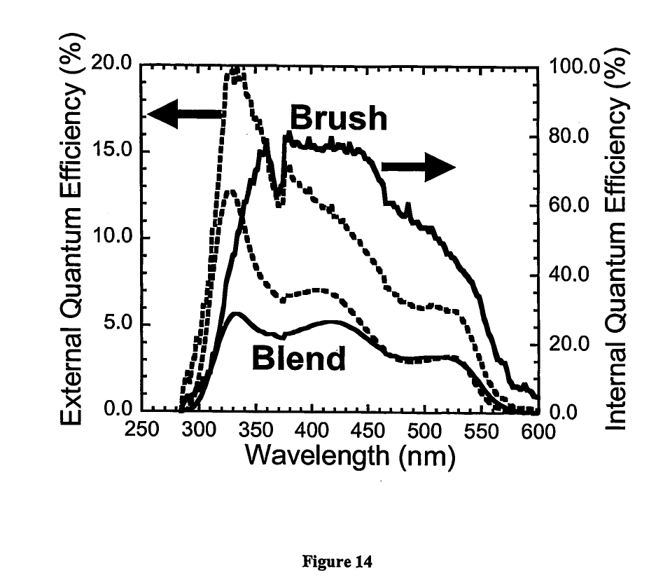

FIG. 14 shows external quantum efficiency (dotted lines) and internal quantum efficiency (solid lines) for photovoltaic devices comprising: SAM modified ITO anode/45 nm thick poly(4-diphenylaminobenzyl acrylate) brush film (grown from the SAM modified ITO anode) coated with cadmium selenide nanocrystals/aluminium cathode (top curves), and ITO anode/100 nm thick polymer nanocrystal blend comprising a 1:8 weight ratio of poly(4-diphenylaminobenzyl acrylate) and cadmium selenide nanocrystals/aluminium cathode (bottom curves).

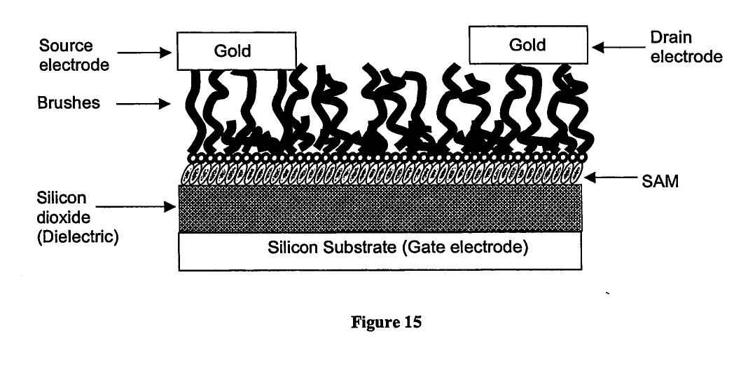

FIG. 15 shows a schematic representation of the structure of a field effect transistor device of the present invention.

### EXAMPLE 1

### Monomer preparation: synthesis of 4-diphenylaminobenzyl acrylate monomer

A solution of 4-(diphenylamino)benzaldehyde (25 g, 92 mmol) in dry THF (100 mL) was added dropwise to a molar excess of a solution of LiAlH₄ (5 g, 132 mmol) in dry THF (80 ml) at room temperature under a nitrogen atmosphere. After three hours stirring, at room temperature, under a nitrogen atmosphere, the reaction mixture was quenched by the addition of demineralised water. The reaction mixture was filtered and the THF layer was removed by rotary evaporation. The solid, in water, was dissolved in DCM and the organic layer was collected. The aqueous layer was extracted with DCM and the organic layers were collected and combined and then washed with brine. The organic layer was collected, dried over anhydrous MgSO₄, filtered, and the solvent evaporated to yield the solid product, 4-diphenylaminobenzyl alcohol (24.5 g, 89 mmol, 97% yield).

A solution of acryloyl chloride (7.2 ml, 89 mmol) in distilled DCM (20 ml) was added dropwise to a mixture of 4-diphenylaminobenzyl alcohol produced above (24 g, 87 mmol) and triethylamine (distilled prior to use over KOH) (13 ml, 93 mmol) in distilled DCM (200 ml) at room temperature under a nitrogen atmosphere. After 18 hours stirring, at room temperature, under a nitrogen atmosphere the reaction mixture was quenched by the addition of 0.01 M HCl (aqueous). The organic layer was collected and the aqueous layer was extracted with DCM. The organic layers were collected and combined and then washed with a saturated NaHCO₃ solution (aqueous), followed by a wash with brine. The organic layer was collected, and dried over anhydrous MgSO₄ and filtered. Some solvent was then evaporated to concentrate the solution and the solution was run though a plug of silica. The solvent was then completely evaporated to yield the solid yellow product, 4-diphenylaminobenzyl acrylate monomer (27.5 g, 84 mmol, 96% yield).

### EXAMPLE 2

### Silane initiator synthesis—synthesis of 2-bromo-2-methyl-propionic acid 3-trichlorosilanyl-propyl ester

2-bromoisobutyryl bromide (1.85 ml, 15 mmol), was added dropwise to a stirred solution of allyl alcohol (1.02 mL, 15 mmol) and triethylamine (2.51 ml, 18 mmol), in DCM (10 ml) at 0° C., under a nitrogen atmosphere. The solution was stirred for 1 hour at 0° C., the temperature was raised to room temperature and the reaction mixture was then stirred for another 3 hours, all under a nitrogen atmosphere. The precipitate was then removed by filtration, the organic layer was washed with saturated NH₄Cl, followed by a wash with water. The organic layer was then dried with anhydrous MgSO₄ and the solvent evaporated on a rotary evaporator. The product was then purified by column chromatography (silica column) using 9:1 hexane:ethyl acetate as the eluant. The solvent was then evaporated to yield the clear, liquid product prop-2-enyl-2-bromo-2-methyl propionate (1.72 g, 55% yield).

To a dry flask under a dry nitrogen atmosphere was added the prop-2-enyl-2-bromo-2-methyl propionate (0.97 g) prepared above and trichlorosilane (15 ml). A solution of hexachloroplatinic acid (21 mg) in a 1:1 (v/v) mixture of ethanol and 1,2-dimethoxyethane (3.75 ml of mixture) was added dropwise to the reaction mixture. The reaction was stirred in the dark, under a dry nitrogen atmosphere for 18 hours. Dry toluene (5 ml) was then added and free trichlorosilane removed under reduced pressure. Dry DCM (20 ml) was added and then removed under vacuum to remove all remaining trichlorosilane. The resulting product was distilled using a Kugelrohr distillation apparatus (200° C., about 11 mm Hg) to give the title product, 2-bromo-2-methyl-propionic acid 3-trichlorosilanyl-propyl ester as a clear, liquid (0.42 g, about 26% yield)

### EXAMPLE 3

### Substrate Preparation: Preparation of ITO-Coated Substrate Having a SAM and ITO-Coated Substrate with a PEDOT/PSS Layer Having a SAM

(a) ITO

First, glass pre-coated with ITO (purchased from Donnelly, Inc.) was cleaned by sonicating in acetone (10 mins) and then sonicating in isopropanol (10 mins). The substrate is then made hydrophillic by treating with a 5:1:1 water:ammonia:hydrogen peroxide mixture for 1 hour at 70° C. [alternatively, the substrates could be made hydrophillic using an oxygen plasma treatment (approximately 30 sec at 100 W)]. At the end of this time, the substrate was cleaned, dried, washed with water, dried with a nitrogen gun and then baked in an oven at 100° C. for 24 hours.

A self-assembled monolayer (SAM) of the initiator prepared in Example 2 above on the hydrophilic ITO-coated substrate obtained above was then prepared either by reacting with said initiator in supercritical CO₂ or by reaction in an solution of said initiator in toluene:

(i) Supercritical CO₂: The ITO slides prepared above were placed in a 10 ml stainless steel high pressure vessel. The silane initiator prepared in Example 2 above (about 2 microlitres) was added to the vessel, and the vessel was filled with CO₂ (1000-3000 psi) and heated to the necessary temperature (20-40° C.). After reaction, the substrate was rinsed by filling the cell with CO₂, and the ITO-coated substrate having a SAM of siloxane molecules were then stored in a dessicator until use.

(ii) Using an intiator solution: A 1 mM solution of the silane initiator prepared in Example 2 above in dry toluene (15 ml) was made up and pushed through a mlllipore filter into a dish containing the ITO slides prepared above. If necessary more toluene was then added to completely cover the slides. Optionally, triethylamine (25-50 microlitres) was then added to the dish. The dish was covered and left at room temperature for a period of time ranging from 1 hour to 10 days. After that time, the slides were removed from the solution and were then, sequentially, washed with toluene, sonicated in toluene, washed with acetone, washed with ethanol and then dried using a stream of nitrogen. The ITO-coated substrate having a SAM of the siloxane molecules were then stored under nitrogen until further use.

(b) ITO Coated with PEDOT/PSS

First, a glass substrate coated with ITO was cleaned and oxygen plasma treated as in 3(a) above. The ITO-coated substrate thus obtained was then spin coated with PEDOT/PSS from an aqueous solution thereof at 4000 rpm for 60 seconds (the ratio of PEDOT:PSS in the solution was 1:16). The PEDOT/PSS-covered ITO-coated glass substrate thus obtained was then baked at 120° C. for 1 hr. At the end of this time, the PEDOT/PSS surface was oxygen plasma treated for 30 seconds at 100 W to give dangling hydroxy groups on the PEDOT/PSS surface.

A poly(dimethylsiloxane) (PDMS) stamp was wetted with a hexane solution of the initiator produced in Example 2 above. The wetted PDMS stamp was pressed gently on the PEDOT/PSS surface for 1 minute under atmospheric conditions resulting in covalent bonding of the siloxane initiator with the dangling hydroxy groups on the PEDOT/PSS surface to give the desired product. As an alternative, it would be possible to deposit the SAM by soaking the substrate in a dilute solution of the silane initiator in a manner similar to that described above for the ITO-coated substrate.

(c) Silicon Dioxide Coated Silicon Substrate

First, a silicon substrate was cleaned and oxygen plasma treated as in 3(a) above giving a thin layer of silicon dioxide on top of the silicon substrate.

A poly(dimethylsiloxane) (PDMS) stamp was wetted with a hexane solution of the initiator produced in Example 2 above. The wetted PDMS stamp was pressed gently on the silicon dioxide surface for 1 minute under atmospheric conditions resulting in covalent bonding of the siloxane initiator with the silicon dioxide surface to give the desired product. As an alternative, it would be possible to deposit the SAM by soaking the substrate in a dilute solution of the silane initiator in a manner similar to that described above for the ITO-coated substrate.

### EXAMPLE 4

### Polymer brush growth: growth of poly(4-diphenylaminobenzyl acrylate) brushes on pre-prepared substrate

The monomer 4-diphenylaminobenzyl acrylate prepared in Example 1 above was dissolved in solvent (usually DMF) at room temperature (although heating to say 90° C. is typically necessary to completely dissolve the monomer), to give a solution having a concentration of approximately 1 g/ml. A ligand, usually N,N,N′,N′,N″-pentamethyldiethylenetriamine (PMDTA) was added followed by an inhibitor, usually copper (II) bromide. The air in the solution was then replaced with nitrogen by bubbling nitrogen through the solution. A catalyst, usually copper (I) bromide, was then added to the solution thus obtained.

Separately, one of the substrates with a SAM prepared in Example 3 above was then taken and placed in a Schlenk tube, and the air in the tube replaced with nitrogen by conducting a number of evacuation/refill cycles. The polymerisation solution prepared above was then transferred into the Schlenk tube containing the substrate as soon as the catalyst had been added. The polymerisation reaction mixture thus obtained was allowed to react for some time at a suitable temperature (typically, for 90 mins at 90° C.) under a nitrogen atmosphere. At the end of this time, the substrate was removed from the tube by washing out with dichloromethane and washed with solvent (e.g. dichloromethane) to give the desired substrate coated with brushes of poly(4-diphenylaminobenzyl acrylate).

### EXAMPLE 5

### Coating Brushes with a 2^{nd} Component: Coating of Substrates Produced in Example 4 with Perylene or Cadmium Selenide Nanocrystals

(a) 1^{st} Method: Drop-Casting Method with Perylene

Perylene was dissolved in p-xylene (a poor solvent for perylene but a good solvent for the brushes) such that the solution was oversaturated and not all the perylene was dissolved. The solution was then heated at 70° C. for 1 hour until all the perylene had dissolved. The brushes on the surface of the substrate prepared in Example 4 above were coated with the hot solution causing the brushes to swell (this can be done in a saturated atmosphere to reduce the rate of solvent evaporation). As the solution cooled, and over time (e.g. 30 minutes), the perylene started to fall out of solution, aggregating about the brushes forming an integrated network and thus produced the desired product with the perylene component intercalated with the polymer brushes of the product. The volume of solution used in this drop casting method used can be varied to form a desired thickness of film. A typical film thickness of 200 nm was achieved with a p-xylene solution having a concentration of 6 g/litre, 0.15 ml of said solution being deposited on a 12 mm by 12 mm square substrate. Alternatively it can be advantageous to use more solution and a more concentrated solution than necessary to form a desired thickness of film. With the latter, spinning the substrate to remove excess solution can take place after a designated time (typically, in the region of 10 minutes).

(b) 2^{nd} Method: Spin-Coating Method with Perylene

This involves spin coating from a solvent common to both perylene and the brushes. The perylene was first dissolved in a suitable solvent such as chloroform, p-xylene or toluene. The brushes of the substrate prepared in Example 4 were then coated with the solution thus obtained and the substrate was spun at a pre-determined rate in order to achieve the desired thickness of film. For example, a solution of perylene in chloroform having a concentration of 25 g perylene/litre was spun at 1500 rpm for 1 second to give a film thickness of approximately 100 nm. The solution can be left on the brushes for a certain period of time before spinning in order to allow the perylene to interpenetrate the brushes. If the perylene prefers the solvent to brushes, it is likely to form a bi-layer with the brushes collapsed beneath the top perylene layer (which is not advantageous). If, however, the perylene prefers the brushes, it may form integrated network as perylene aggregates about brushes. It may be advantageous to use a mixture of solvents in order to achieve this regime, for example chloroform containing 1% methanol.

(c) 3^{rd} Method: Alternative Spin-Coating Method with Perylene

The brushes of the substrate prepared in Example 4 were coated with a solution of perylene in chloform or p-xylene. This was then spun instantly for a short time, typically 1 second. This is long enough to achieve a uniform film; however, not all the solvent has evaporated. The substrate was then allowed to dry slowly under a saturated atmosphere of chloroform or p-xylene so that the perylene and the brushes had time to form an integrated network.

(d) 4^{th} Method: Spin-Coating Method with Cadmium Selenide Nanocrystals

The cadmium selenide crystals were prepared according to the procedure described in Peng, Z. A.; Peng, X. G. J. Am. Chem. Soc. 124, 3343—(2002). The crystals were estimated to have a diameter of 2.6 nm by their absorption spectra. The brushes of the substrate prepared in Example 4 were soaked in a solution of these nanocrystals (25 g/l 1:10 pyridine:chloroform) for 30 minutes in a chloroform solvent-saturated atmosphere. After soaking, the substrates were carefully placed on a spin-coater and the excess solution spun off. The resulting prepared substrates were annealed at 150° C. for 30 minutes to ensure all the pyridine was removed.

(e) 5^{th} Method: Drop-Casting Method with Cadmium Selenide Nanocrystals

The brushes of the substrate prepared in Example 4 were soaked in a solution of cadmium selenide crystals prepared as described in Example 5(d) above (25 g/11:10 pyridine:chloroform) for 30 minutes in a chloroform solvent-saturated atmosphere. After soaking, the solvent was allowed to evaporate off, leaving a thick coating of cadmium selenide nanocrystals upon the brush substrate. The prepared substrates were subsequently annealed at 150° C. for 30 minutes to ensure all the pyridine was removed. The advantage of method 5 over method 4 is that it is possible to obtain a much thicker layer of nanocrystals within the brushes.

(f) 6^{th} Method: Electroplating Method with Cadmium Selenide Nanocrystals

The brushes of the substrate prepared in Example 4 were soaked in a solution of cadmium selenide crystals prepared as described in Example 5(d) above (25 g/11:10 pyridine:chloroform). A further electrode (cathode) was then placed in contact with the solution above the anode. A voltage was then applied to the cathode to induce an electric field through the solution perpendicular to the brush coated substrate. The function of the electric field is two fold, the electric field causes the polymer brushes prepared in Example 4 to stretch away from, normal to, the anode surface, furthermore, the electric field causes the cadmium selenide crystals to migrate towards the anode and fill the space between the polymer brushes. After a specified time, i.e. 5 minutes, the electric field is switched off, the cathode removed and the excess solution removed from on top of the brushes via spin-coating.

### EXAMPLE 6

### Deposition of Cathode: Coating of Second Component Layer Produced in Example 5 with Cathode Material

The cathode was deposited on top of the product of Example 5 by a process of thermal evaporation under high vacuum of 10⁻⁶ milli bar. The material used for the cathode was either aluminum, magnesium or calcium.

A photovoltaic device produced according to Example 6, having a SAM of the initiator produced in Example 2 above on the PEDOT/PSS covered ITO-coated glass substrate produced according to Example 3(b) above, poly(4-diphenylaminobenzyl acrylate) brushes grown from said SAM initiator according to Example 4, coated with perylene according to Example 5(b) above and then coated with aluminium according to Example 6 above was tested for its device characteristics. The absorbtion spectra of poly(4-diphenylaminobenzyl acrylate) and perylene are shown in FIG. 6, the external quantum efficiency (EQE spectra) for the brush device of the invention and an equivalent prior art device having a semiconducting layer comprising a blend of poly(4-diphenylaminobenzyl acrylate) and perylene (fabricated according to the procedure described in H. J. Snaith et al., Nano. Lett., 2002, 2, 12, apart from chloroform being used as the solvent in place of the p-xylene used in said reference) are shown in FIG. 7, and AFM images for a complete covering of brushes grown from a silicon substrate, the brushes grown on an ITO substrate and an ITO substrate are shown in FIG. 8.

As can be seen from the EQE spectra, the device of the present invention was 2% efficient at peak wavelength. From the AFM Images of the brush film, there was not a very thick covering of brushes, and further work needs to be done to optimise the application of the second component. However, from these results it is clear that devices of the present invention having semiconducting polymer brushes have very interesting performance characteristics which makes the use of semiconducting polymer brushes very promising as a means of maximising the performance of blend devices.

A diode was fabricated, having a SAM of the initiator produced in Example 2 above on the ITO-coated glass substrate produced according to Example 3(a) above, poly(4-diphenylaminobenzyl acrylate) brushes grown from said SAM initiator according to Example 4, a spin-coated (4000 rpm) PEDOT:PSS cathode (about 40 nm thick) and an evaporated gold film (about 100 nm thick) as a contact, and this was tested for its device characteristics. Furthermore, a spin-coated film of poly(4-diphenylaminobenzyl acrylate) on an ITO-coated glass substrate, a spin-coated (4000 rpm) PEDOT:PSS cathode (about 40 nm thick) and an evaporated gold film (about 100 nm thick) as a contact, was also tested for its device characteristics. The current-voltage characteristics are shown in FIG. 9; the poly(4-diphenylaminobenzyl acrylate) brush diode supports a much higher current density than the diode comprising the spin-coated film of poly(4-diphenylaminobenzyl acrylate). From these results it is clear that polymer brushes will be suitable for transporting charge out of (in the case of photovoltaic devices) or into (in the case of electroluminescent devices) a diode.

The AFM images of a polymer brush film [poly(4-diphenylaminobenzyl acrylate) brushes] produced according to Example 4, a cadmium selenide nanocrystal film spin-coated on an ITO substrate and a cadmium selenide nanocrystal coated polymer brush film [poly(4-diphenylaminobenzyl acrylate) brushes] produced according to Example 5(d) are shown in FIG. 12. It should be noted that the image of the cadmium selenide nanocrystal coated polymer brush film is more similar to the image of the polymer brush film than the cadmium selenide nanocrystal film spin-coated on an ITO substrate, suggesting that the cadmium selenide nanocrystals have an attraction to the polymer brushes, and that the polymer brushes are close to if not at the surface of the film.

The UV-vis absorption spectra of a polymer brush film [poly(4-diphenylaminobenzyl acrylate) brushes] produced according to Example 4, a cadmium selenide nanocrystal film spin-coated on an ITO substrate and a cadmium selenide nanocrystal coated polymer brush film [poly(4-diphenylaminobenzyl acrylate) brushes] produced according to Example 5b are shown in FIG. 13. It should be noted that the absorbance peak at 530 nm of the cadmium selenide nanocrystal film spin-coated on an ITO substrate and the cadmium slenide nanocrystal coated polymer brush film is the same, implying that the polymer brush film has an uptake of approximately 25 nm of cadmium selenide nanocrystals.

A poly(4-diphenylaminobenzyl acrylate) brush diode produced according to the procedure of Example 6, having a SAM of the initiator produced in Example 2 above on the ITO-coated glass substrate produced according to Example 3(a) above, poly(4-diphenylaminobenzyl acrylate) brushes grown from said SAM initiator according to Example 4, capped with a PEDOT:PSS anode via spin-coating, and then coated with gold according to Example 6 above was tested for its device characteristics. A photovoltaic device produced according to Example 6, having a SAM of the initiator produced in Example 2 above on the ITO-coated glass substrate produced according to Example 3(a) above, poly(4-diphenylaminobenzyl acrylate) brushes grown from said SAM initiator according to Example 4, coated with cadmium selenide nanocrystals according to Example 5(d) above and then coated with aluminium according to Example 6 above was also tested for its device characteristics. The current-voltage characteristics shown in FIG. 13, for the photovoltaic device produced as above show a much higher current density than the poly(4-diphenylaminobenzyl acrylate) brush diode produced as above. The cadmium selenide nanocrystals have much higher charge mobility than poly(4-diphenylaminobenzyl acrylate) brushes. This implies that there are paths within the cadmium selenide nanocrystal phase which traverse the film from anode to cathode, i.e. the cadmium selenide nanocrystals completely intercalate with the brushes. As can be seen from the EQE and IQE spectra of FIG. 14, the brush device significantly outperformed an optimised blend device, produced according to Example 6, having a 100 nm thick spin-coated film of 1:8 poly(4-diphenylaminobenzyl acrylate): cadmium selenide by weight on the ITO-coated glass substrate and then coated with aluminium according to Example 6 above. The brush device has a near unity conversion rate for absorbed photons to collected electrons. This is significant evidence that polymer brushes used in optoelectronic devices could become seriously competitive with other future generation electronics.

### EXAMPLE 7

### Characterisation of Interpenetrated Polymer Brush Films

A polymer brush film coated with rhodamine dye was produced to study interpenetration characteristics. It was produced according to Example 5, having a SAM of the initiator produced in Example 2 above on the ITO-coated glass substrate produced according to Example 3(a) above, poly(4-diphenylaminobenzyl acrylate) brushes grown from said SAM initiator according to Example 4, and spin-coated with rhodamine dye according to Example 5(b). In order to test the degree of interpenetration achieved an oxygen plasma barrel etcher was used in combination with UV-vis spectroscopy to examine the interior structure of the film. The oxygen plasma ablated the surface of the organic film at a steady rate (˜5 nm/minute for both polymer and dye) and the absorption spectra of the film was measured with UV-vis spectroscopy after intervals of treatment. The composition of the remaining material was determined by comparing the intensity of the absorption peaks of the poly(4-diphenylaminobenzyl acrylate) and rhodamine dye. Rhodamine dye has an absorption peak at 580 nm, where there is negligible absorption from the brushes, so the relative thickness of this component can be directly calculated. The absorption peak of the brushes is at 305 nm, where there is still some absorption from the dye, however, this is accounted for by subtracting this contribution. From the absorption spectra shown in FIG. 10 it can be seen that after 5 minutes of etching the absorbance at 305 nm is comparable to that of the pristine brush film prior to coating with dye. However, there is still a considerable absorption form the dye (absorbance ˜0.24 at 580 nm corresponds to 46 nm thick pristine dye film) implying that the dye has significantly interpenetrated the poly(4-diphenylaminobenzyl acrylate) brush film. The equivalent thickness of each component can be estimated as a function of film thickness from the absorption spectra. From the top figure of FIG. 11 it is apparent that the brushes are extended up to 100 nm in length and that there is still dye present when the total film thickness is less than 15 nm. This thickness profile is equivalent to an integration of the film composition over the remaining film thickness. The differential of this profile gives the composition of the film as a function of position from substrate, and this is shown in the second figure of FIG. 11. This provides strong evidence to suggest that the polymer and dye are vertically organised in two opposite concentration gradients achieving an interpenetrating network when the poly(4-diphenylaminobenzyl acrylate) brushes are coated with a second component.

### EXAMPLE 8

### Field Effect Transistor Fabrication: Fabrication of field effect transistor incorporating poly(4-diphenylaminobenzyl acrylate) brushes grown form a silicon dioxide-coated silicon substrate

A field effect transistor was fabricated, having a SAM of the initiator produced in Example 2 above on a silicon dioxide-coated silicon substrate produced according to Example 3(b) above (except a clean silicon dioxide-coated silicon substrate was used in place of the PEDOT:PSS-coated ITO-coated glass substrate used in Example 3(b)), poly(4-diphenylaminobenzyl acrylate) brushes grown from said SAM initiator according to Example 4, and coated with gold, as the source and drain electrodes, according to Example 6 above. A schematic illustration of device structure is shown in FIG. 15.

What is claimed is:

1. An organic electronic device comprising at least two electrodes and a semiconducting layer comprising a mixture of at least one hole-transporting semiconducting material and at least one electron-transporting semiconducting material, wherein at least one of said semiconducting materials comprises semiconducting polymer brushes attached to a surface of at least one of said electrodes and in contact with at least one of said other semiconducting materials.

2. The organic electronic device according to claim 1, wherein contact between said semiconducting polymer brushes attached to the electrode and said at least one other semiconducting material is achieved by:
(a) intercalation of said at least one other semiconducting material with said semiconducting polymer brushes;
(b) growth of said at least one other semiconducting material as further semiconducting polymer brushes in gaps between said first semiconducting polymer brushes to give an interpenetrating mixed polymer network; or
(c) polymerisation of a second, different monomer from the end of said semiconducting polymer brushes to give block co-polymer brushes having a bi-layer structure with direct covalent bonds between at least two semiconducting materials.

3. The organic electronic device according to claim 1, wherein said device is selected from the group consisting of electroluminescent devices, photovoltaic devices, field effect transistors, and liquid crystal devices.

4. The organic electronic device according to claim 3, wherein said device comprises a photovoltaic device.

5. The organic electronic device according to claim 3, wherein said device comprises an electroluminescent device.

6. The organic electronic device according to claim 1, wherein the average length of the polymer brushes is from 1 nm to 1 μm.

7. The organic electronic device according to claim 1, wherein the average length of the polymer brushes is at least 40 nm.

8. The organic electronic device according to claim 1, wherein said semiconducting polymer brushes are brushes comprise a polymer is selected from the group consisting of poly-phenylene-vinylene (PPV) and derivatives thereof, polyfluorene derivatives, polynaphthylene derivatives, polyindenofluorene derivatives, polyphenanthrenyl derivatives, and poly(acrylate) derivatives.

9. The organic electronic device according to claim 1, wherein said semiconducting polymer brushes comprise a polymer unit selected from the group consisting of formulae (I), (VIII), (IX), (X), (XI), (XII), (XIII), (XIV) or (XV): 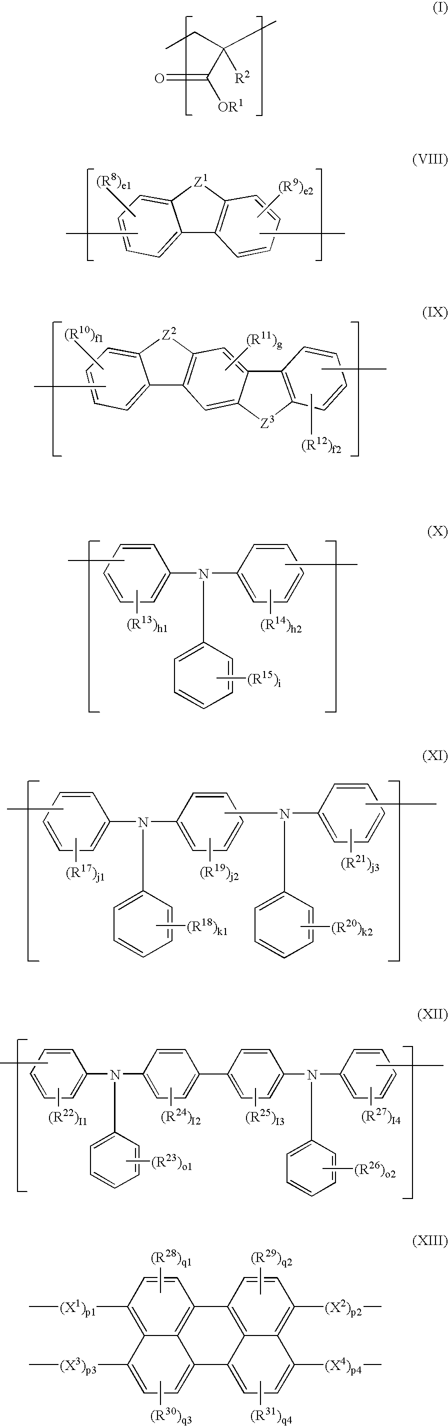 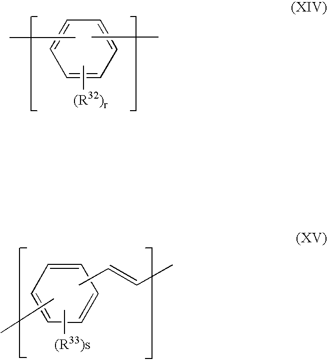
wherein:
R¹ is a group of formula —(CH₂)ₘ—X—Y wherein
m is 0 or an integer of from 1 to 6,
X is a group of formula (X), (XI), (XII), (XIII), (XIV) or (XV) as defined above or a group of formula (II) or (III) as defined below 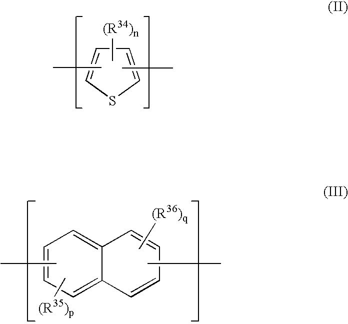
wherein
n is 0, 1 or 2,
p and q are the same or different and each is 0 or an integer of from 1 to 3, and
each of R³⁴, R³⁵ and R³⁶ is the same or different and is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is selected from the group consisting of hydroxy groups, alkyl groups as defined below, haloalkyl groups as defined below, alkoxy groups as defined below, alkoxyalkyl groups as defined below, aryl groups as defined below, aryloxy groups as defined below, aralkyl groups as defined below, amino groups, alkylamino groups the alkyl moiety of which is as defined below, dialkylamino groups wherein each alkyl moiety is the same or different and is as defined below, aralkyloxy groups the aralkyl moiety of which is as defined below and haloalkoxy groups comprising an alkoxy group as defined below which is substituted with at least one halogen atom,
or, where n, p or q is an integer of 2, the 2 R³⁴ groups, the two R³⁵ groups or the two R³⁶ groups respectively may, together with the ring carbon atoms to which they are attached, form an aryl group as defined below or a heterocyclic group having from 5 to 7 ring atoms, one or more of said ring atoms being a heteroatom selected from the group consisting of nitrogen, oxygen and sulfur atoms, and
Y is selected from the group consisting of a hydrogen atom, R³⁷, NHR³⁸ and NR³⁸R³⁹, wherein
R³⁷ is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is as defined above, and
each of R³⁸ and R³⁹ is the same or different and is selected from the group consisting of aryl groups as defined below and aralkyl groups as defined below;
R² is selected from the group consisting of group consisting of hydrogen atoms, alkyl groups as defined below, haloalkyl groups as defined below and alkoxy groups as defined below;
each of R⁸ to R¹⁵ and R¹⁷ to R³³ is the same or different and is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is as defined above,
or, where r or s is an integer of 2, the 2 groups R³² or R³³ respectively may, together with the ring carbon atoms to which they are attached, form a heterocyclic group having from 5 to 7 ring atoms, one or more of said ring atoms being a heteroatom selected from the group consisting Of nitrogen, oxygen and sulfur atoms;
each of Z¹, Z² and Z³ is the same or different and is selected from the group consisting of O, S, SO, SO₂, NR³, N⁺(R^{3′})(R^{3″}), C(R⁴)(R⁵), Si(R^{4′})(R⁵) and P(O)(OR⁶), wherein R³, R^{3′} and R^{3″} are the same or different and each is selected from the group consisting of hydrogen atoms, alkyl groups as defined below, haloalkyl groups as defined below, alkoxy groups as defined below, alkoxyalkyl groups as defined below, aryl groups as defined below, aryloxy groups as defined below, aralkyl groups as defined below, and alkyl groups as defined below which are substituted with at least one group of formula —N⁺(R⁷)₃ wherein each group R⁷ is the same or different and is selected from the group consisting of hydrogen atoms, alkyl groups as defined below and aryl groups as defined below, R⁴, R⁵, R^{4′} and R^{5′} are the same or different and each is selected from the group consisting of hydrogen atoms, alkyl groups as defined below, haloalkyl groups as defined below, alkoxy groups as defined below, halogen atoms, nitro groups, cyano groups, alkoxyalkyl groups as defined below, aryl groups as defined below, aryloxy groups as defined below and aralkyl groups as defined below or R⁴ and R⁵ together with the carbon atom to which they are attached represent a carbonyl group, and R⁶ is selected from the group consisting of hydrogen atoms, alkyl groups as defined below, haloalkyl groups as defined below, alkoxyalkyl groups as defined below, aryl groups as defined below, aryloxy groups as defined below and aralkyl groups as defined below;
each of X¹, X², X³ and X⁴ is the same or different and is selected from:
arylene groups which are aromatic hydrocarbon groups having from 6 to 14 carbon atoms in one or more rings which may optionally be substituted by at least one substituent selected from the group consisting of nitro groups, cyano groups, amino groups, alkyl groups as defined below, haloalkyl groups as defined below, alkoxyalkyl groups as defined below, aryloxy groups as defined below and alkoxy groups as defined below;
straight or branched-chain alkylene groups having from 1 to 6 carbon atoms;
straight or branched-chain alkenylene groups having from 2 to 6 carbon atoms; and
straight or branched-chain alkynylene groups having from 1 to 6 carbon atoms; or X¹ and
X² together and/or X³ and X⁴ together can represent a linking group of formula (V) below: 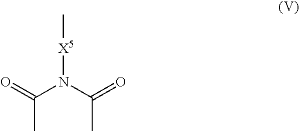
wherein X⁵ represents an arylene group which is an aromatic hydrocarbon group having from 6 to 14 carbon atoms in one or more rings which may optionally be substituted by at least one substituent selected from the group consisting of nitro groups, cyano groups, amino groups, alkyl groups as defined below, haloalkyl groups as defined below, alkoxyalkyl groups as defined below, aryloxy groups as defined below and alkoxy groups as defined below;
each of e1, e2, f1 and f2 is the same or different and is 0 or an integer of 1 to 3;
each of g, q1, q2, q3 and q4 is the same or different and is 0, 1 or 2;
each of h1, h2, j1, j2, j3, l1, l2, l3, l4, r and s is the same or different and is 0 or an integer of 1 to 4;
each of i, k1, k2, o1 and o2 is the same or different and is 0 or an integer of 1 to 5;
and
each of p1, p2, p3 and p4 is 0 or 1;
the alkyl groups above are straight or branched-chain alkyl groups having from 1 to 20 carbon atoms;
the haloalkyl groups above are alkyl groups as defined above which are substituted with at least one halogen atom;
the alkoxy groups above are straight or branched-chain alkoxy groups having from 1 to 20 carbon atoms;
the alkoxyalkyl groups above are alkyl groups as defined above which are substituted with at least one alkoxy group as defined above; and
the aryl group above and the aryl moiety of the aralkyl groups (which have from 1 to 20 carbon atoms in the alkyl moiety) and the aryloxy groups above is an aromatic hydrocarbon group having from 6 to 14 carbon atoms in one or more rings which may optionally be substituted with at least one substituent selected from the group consisting of nitro groups, cyano groups, amino groups, alkyl groups as defined above, haloalkyl groups as defined above, alkoxyalkyl groups as defined above and alkoxy groups as defined above.

10. The organic electronic device according to claim 9, wherein said semiconducting brushes comprise homopolymeric brushes comprising units of formulae (I), (VIII), (IX), (X), (XIV) or (XV).

11. The organic electronic device according to claim 1, wherein said semiconducting polymer brushes comprise a polymer selected from the group consisting of poly(4-diphenylaminobenzyl acrylate), PPV, poly(2-methoxy-5-(2′-ethyl)hexyloxy-phenylene-vinylene) (MEH-PPV), dialkoxy derivatives of PPV, dialkyl derivatives of PPV, and polyfluorene derivatives.

12. The organic electronic device according to claim 1, wherein said semiconducting polymer brushes comprise a polymer selected from the group consisting of poly(4-diphenylaminobenzyl acrylate), PPV, MEH-PPV, poly(2,7-(9,9-di-n-hexylfluorene)), poly(2,7-(9,9-di-n-octylfluorene)), poly(2,7-(9,9-di-n-octylfluorene)-(1,4-phenylene-((4-sec-butylphenyl)imino)-1,4-phenylene)) (TFB), and poly(2,7-(9,9-di-n-octylfluorene)-3,6-benzothiadiazole) (F8BT).

13. The organic electronic device according to claim 1, wherein said at least one other semiconducting material comprises a semiconducting polymeric material or a semiconducting small organic molecule.

14. The organic electronic device according to claim 13, wherein said at least one other semiconducting material comprises a semiconducting polymer selected from the group consisting of poly-phenylene-vinylene (PPV) and derivatives thereof, polyfluorene derivatives, polynaphthylene derivatives, polyindenofluorene derivatives, polyphenanthrenyl derivatives, and poly(acrylate) derivatives, or comprises a semiconducting small organic molecule selected from the group consisting of aluminium quinolinol complexes, perylene and derivatives thereof, complexes of transition metals, lanthanides, and actinides with organic ligands.

15. The organic electronic device according to claim 14, wherein said semiconducting material comprises a polymer unit selected from the group consisting of formulae (VIII), (IX), (X), (XI), (XII), (XIII), (XIV) or (XV): 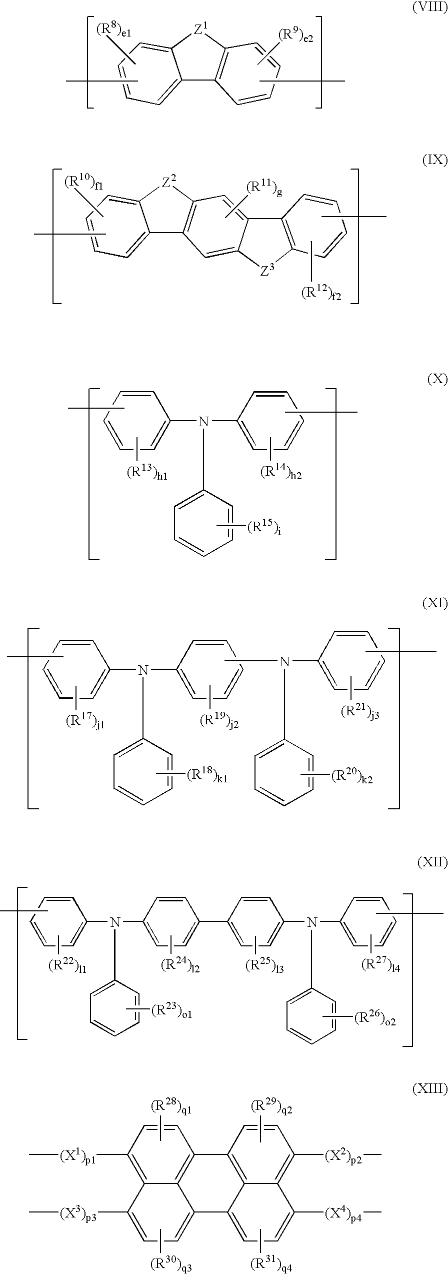 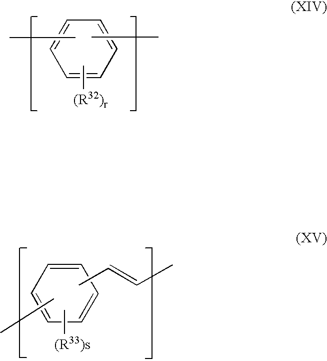
wherein:
R¹ is a group of formula —(CH₂)ₘ—X—Y wherein
m is 0 or an integer of from 1 to 6,
X is a group of formula (X), (XI), (XII), (XIII), (XIV) or (XV) as defined above or a group of formula (II) or (III) as defined below 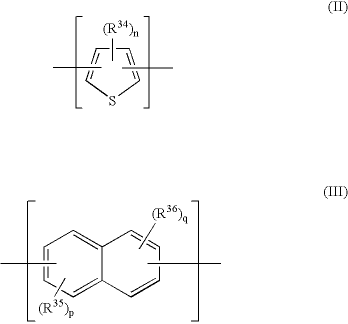
wherein
n is 0, 1 or 2,
p and q are the same or different and each is 0 or an integer of from 1 to 3, and
each of R³⁴, R³⁵ and R³⁶ is the same or different and is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is selected from the group consisting of hydroxy groups, alkyl groups as defined below, haloalkyl groups as defined below, alkoxy groups as defined below, alkoxyalkyl groups as defined below, aryl groups as defined below, aryloxy groups as defined below, aralkyl groups as defined below, amino groups, alkylamino groups the alkyl moiety of which is as defined below, dialkylamino groups wherein each alkyl moiety is the same or different and is as defined below, aralkyloxy groups the aralkyl moiety of which is as defined below and haloalkoxy groups comprising an alkoxy group as defined below which is substituted with at least one halogen atom,
or, where n, p or q is an integer of 2, the 2 R³⁴ groups, the 2 R³⁵ groups, or the 2 R³⁶ groups respectively may, together with the ring carbon atoms to which they are attached, form an aryl group as defined below or a heterocyclic group having from 5 to 7 ring atoms, one or more of said ring atoms being a heteroatom selected from the grout consisting of nitrogen, oxygen and sulfur atoms, and
Y is selected from the group consisting of a hydrogen atom, R³⁷, NHR³⁸ and NR³⁸R³⁹, wherein
R³⁷ is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is as defined above, and
each of R³⁸ and R³⁹ is the same or different and is selected from the group consisting of aryl groups as defined below and aralkyl groups as defined below;
R² is selected from the group consisting of group consisting of hydrogen atoms, alkyl groups as defined below, haloalkyl groups as defined below and alkoxy groups as defined below;
each of R⁸ to R¹⁵ and R¹⁷ to R³³ is the same or different and is selected from the group consisting of alkyl groups as defined below, haloalkyl groups as defined below, alkoxy groups as defined below, alkoxyalkyl groups as defined below, aryl groups as defined below, aryloxy groups as defined below, aralkyl groups as defined below and groups of formula —COR¹⁶ wherein R¹⁶ is as defined above,
or, where r or s is an integer of 2, the 2 groups R³² or R³³ respectively may, together with the ring carbon atoms to which they are attached, form a heterocyclic group having from 5 to 7 ring atoms, one or more of said ring atoms being a heteroatom selected from the group consisting of nitrogen, oxygen and sulfur atoms:
each of Z¹, Z² and Z³ is the same or different and is selected from the group consisting of O, S, SO, SO₂, NR³, N⁺(R^{3′})(R^{3″}), C(R⁴)(R⁵), Si(R^{4′})(R^{5′}) and P(O)(OR⁶), wherein R³, R^{3′} and R^{3″} are the same or different and each is selected from the group consisting of hydrogen atoms, alkyl groups as defined below, haloalkyl groups as defined below, alkoxy groups as defined below, alkoxyalkyl groups as defined below, aryl groups as defined below, aryloxy groups as defined below, aralkyl groups as defined below, and alkyl groups as defined below which are substituted with at least one group of formula —N⁺(R⁷)₃ wherein each group R⁷ is the same or different and is selected from the group consisting of hydrogen atoms, alkyl groups as defined below and aryl groups as defined below, R⁴, R⁵, R^{4′} and R^{5′} are the same or different and each is selected from the group consisting of hydrogen atoms, alkyl groups as defined below, haloalkyl groups as defined below, alkoxy groups as defined below, halogen atoms, nitro groups, cyano groups, alkoxyalkyl groups as defined below, aryl groups as defined below, aryloxy groups as defined below and aralkyl groups as defined below or R⁴ and R⁵ together with the carbon atom to which they are attached represent a carbonyl group, and R⁶ is selected from the group consisting of hydrogen atoms, alkyl groups as defined below, haloalkyl groups as defined below, alkoxyalkyl groups as defined below, aryl groups as defined below, aryloxy groups as defined below and aralkyl groups as defined below;
each of X¹, X², X³ and X⁴ is the same or different and is selected from:
arylene groups which are aromatic hydrocarbon groups having from 6 to 14 carbon atoms in one or more rings which may optionally be substituted by at least one substituent selected from the group consisting of nitro groups, cyano groups, amino groups, alkyl groups as defined below, haloalkyl groups as defined below, alkoxyalkyl groups as defined below, aryloxy groups as defined below and alkoxy groups as defined below;
straight or branched-chain alkylene groups having from 1 to 6 carbon atoms;
straight or branched-chain alkenylene groups having from 2 to 6 carbon atoms; and
straight or branched-chain alkynylene groups having from 1 to 6 carbon atoms; or X¹ and
X² together and/or X³ and X⁴ together can represent a linking group of formula (V) below: 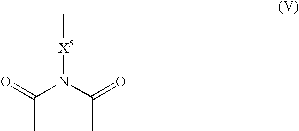
wherein X⁵ represents an arylene group which is an aromatic hydrocarbon group having from 6 to 14 carbon atoms in one or more rings which may optionally be substituted by at least one substituent selected from the group consisting of nitro groups, cyano groups, amino groups, alkyl groups as defined below, haloalkyl groups as defined below, alkoxyalkyl groups as defined below, aryloxy groups as defined below and alkoxy groups as defined below;
each of e1, e2, f1 and f2 is the same or different and is 0 or an integer of 1 to 3;
each of g, q1, q2, q3 and q4 is the same or different and is 0, 1 or 2;
each of h1, h2, j1, j2, j3, l1, l2, l3, l4, r and s is the same or different and is 0 or an integer of 1 to 4;
each of i, k1, k2, o1 and o2 is the same or different and is 0 or an integer of 1 to 5; and
each of p1, p2, p3 and p4 is 0 or 1;
the alkyl groups above are straight or branched-chain alkyl groups having from 1 to 20 carbon atoms;
the haloalkyl groups above are alkyl groups as defined above which are substituted with at least one halogen atom,
the alkoxy groups above are straight or branched-chain alkoxy groups having from 1 to 20 carbon atoms;
the alkoxyalkyl groups above are alkyl groups as defined above which are substituted with at least one alkoxy group as defined above; and
the aryl group above and the aryl moiety of the aralkyl groups (which have from 1 to 20 carbon atoms in the alkyl moiety) and the aryloxy groups above is an aromatic hydrocarbon group having from 6 to 14 carbon atoms in one or more rings which may optionally be substituted with at least one substituent selected from the group consisting of nitro groups, cyano groups, amino groups, alkyl groups as defined above, haloalkyl groups as defined above, alkoxyalkyl groups as defined above and alkoxy groups as defined above.

16. The organic electronic device according to claim 14, wherein said semiconducting polymers comprise a polymer selected from the group consisting of poly(4-diphenylaminobenzyl acrylate), PPV, poly(2-methoxy-5-(2′-ethyl)hexyloxy-phenylene-vinylene) (MEH-PPV), dialkoxy derivatives of PPV, dialkyl derivatives of PPV, and polyfluorene derivatives.

17. The organic electronic device according to claim 14, wherein said semiconducting polymers comprise a polymer selected from the group consisting of poly(4-diphenylaminobenzyl acrylate), PPV, MEH-PPV, poly(2,7-(9,9-di-n-hexylfluorene)), poly(2,7-(9,9-di-n-octylfluorene)), poly(2,7-(9,9-di-n-octylfluorene)-(1,4-phenylene-((4-sec-butylphenyl)imino)-1,4-phenylene)) (TFB), and poly(2,7-(9,9-di-n-octylfluorene)-3,6-benzothiadiazole) (F8BT).

18. The organic electronic device according to claim 14, wherein said semiconducting small organic molecule comprises a molecule selected from the group consisting of aluminium quinolinol complexes and perylene and derivatives thereof.

19. The organic electronic device according to claim 1, wherein said at least one other semiconducting material comprises a semiconducting nanocrystalline material.

20. The organic electronic device according to claim 19, wherein said semiconducting nanocrystalline material comprises a semiconducting nanocrystal selected from the group consisting of cadmium selenide, lead selenide, zinc selenide, cadmium sulphide and zinc sulphide.

21. The organic electronic device according to claim 20, wherein said semiconducting material comprises cadmium selenide nanocrystals.

22. The organic electronic device according to claim 1, wherein said electrode is coated with a hole-transport layer or an electron-transport layer before said polymer brushes are attached thereto.

23. The organic electronic device according to claim 1, wherein said device comprises polymer brushes of only a single species.

24. A process for manufacturing an organic electronic device, said process comprising:
(a) coating a substrate with a material to form a first electrode;
(b) optionally coating the first electrode thus formed with a self-assembled monolayer end-capped with an initiator group or a self-assembled monolayer with the capability of forming a free radical;
(c) bringing the first electrode, optionally coated with the self-assembled monolayer produced in step (b), into contact with a solution of a monomer under conditions suitable for the growth of polymer brushes comprising said monomer from the surface of said electrode;
(d) treating the product of step (c) in such a way as to produce a product in which the polymer brushes are in contact with at least one further semiconducting material; and
(e) coating a material on a top surface of the product of step (d) to form a further electrode.

25. The process according to claim 24, wherein said self-assembled monolayer comprises thiol molecules or siloxane molecules end-capped with an initiator group.

26. The process according to claim 24, wherein a hole transport layer or electron transport layer is deposited before optional step (b) or step (c).

27. An organic electronic device comprising at least two electrodes and a semiconducting layer comprising at least one hole-transporting semiconducting material or at least one electron-transporting semiconducting material, wherein said at least one semiconducting material comprises semiconducting polymer brushes attached to a surface of at least one of said electrodes.

28. The organic electronic device according to claim 27, wherein the device comprises a field effect transistor.

29. A process for manufacturing an organic electronic device, said process comprising:
(a) coating a substrate with a material to form a first electrode;
(b) optionally coating the first electrode with a layer of an electronically insulating material;
(c) optionally coating the first electrode of step (a), or the electrode formed following optional step (b), with a self-assembled monolayer end-capped with an initiator group or a self-assembled monolayer with the capability of forming a free radical;
(d) bringing the electrode formed in step (a) or optional step (b), either electrode form optionally coated with the self-assembled monolayer produced in step (c), into contact with a solution of a monomer under conditions suitable for growth of polymer brushes comprising said monomer from a surface of said electrode;
(e) optionally coating the polymer brushes formed in (d) with a layer of an electronically insulating material; and
(f) coating a material on a top surface of the product of step (d), or following optional step (e), to form a further electrode.

30. The process according to claim 29, wherein the electrode formed in step (a)—is coated with a layer of an electronically insulating material, as step (b).

31. The process according to claim 29, wherein the polymer brushes formed in step (d) are coated with a layer of an electronically insulating material, as step (e).

32. The organic electronic device according to claim 14, wherein the semiconducting, small organic molecule comprises actinides with organic ligands-selected from the group consisting of TMHD, quinacridone, rubrene, and styryl dyes.
